(19) United States
(12) Patent Application Publication
(10) Pub. No.: US 2026/0128113 A1
(43) Pub. Date: May 7, 2026

(54) MEMORY, STORAGE DEVICE, AND MEMORY OPERATION METHOD

(71) Applicant: CXMT Corporation, Hefei (CN)

(72) Inventors: Kanyu Cao, Hefei (CN); Zequn Huang, Hefei (CN); Hongwen Li, Hefei (CN); Enpeng Gao, Hefei (CN)

(73) Assignee: CXMT Corporation, Hefei (CN)

(21) Appl. No.: 19/425,058

(22) Filed: Dec. 18, 2025

Related U.S. Application Data
(63) Continuation of application No. PCT/CN2025/116873, filed on Aug. 26, 2025.

(30) Foreign Application Priority Data
Oct. 18, 2024 (CN) 202411455538.1

(51) Int. Cl. G11C 29/42

(52) U.S. Cl. CPC G11C 29/42

(57) ABSTRACT

A memory includes: multiple data storage blocks and a check code storage block; and a data check circuit, configured to: respectively obtain stored data and a corresponding first check code from the multiple data storage blocks and the check code storage block, and determine, in response to a received mode selection signal, whether to perform a data check operation. The data check circuit is further configured to: perform data check on the stored data based on the first check code, and output the stored data obtained after the data check as first read data, when the mode selection signal indicates that the memory is in an on-die check mode; or directly output the stored data and the first check code as second read data when the mode selection signal indicates that the memory is in an off-die check mode.

### CROSS-REFERENCE TO RELATED APPLICATIONS

This is a continuation application of International Application No. PCT/CN2025/116873 filed on August 26, 2025, which claims priority to Chinese Patent Application No.202411455538.1 filed on October 18, 2024. The disclosures of the above-referenced applications are hereby incorporated by reference in their entirety.

### TECHNICAL FIELD

Embodiments of the present disclosure relate to the field of semiconductor technologies, and in particular, to a memory, a storage device, and a memory operation method.

### BACKGROUND

With rapid development of computer technologies, requirements for a capacity and a speed of a memory are constantly increased. However, as the memory capacity increases, the possibility of a data error also increases. To improve reliability of data processing, an ECC (error checking and correction) check technology is widely applied to a dynamic random access memory (Dynamic Random Access Memory, DRAM). The ECC check is performed to check and correct a specific quantity of errors by encoding data, thereby reducing a failure rate of a storage system.

However, at present, implementation of a mainstream ECC check scheme in a storage device on the market requires support from an additional hardware circuit and algorithm, increasing costs for producing a DRAM storage device.

### SUMMARY

Embodiments of the present disclosure provide a memory, a storage device, and a memory operation method. According to a first aspect, an embodiment of the present disclosure provides a memory. The memory includes: multiple data storage blocks and a check code storage block; and a data check circuit, configured to: respectively obtain stored data and a corresponding first check code from the multiple data storage blocks and the check code storage block, and determine, in response to a received mode selection signal, whether to perform a data check operation. The data check circuit is further configured to: perform data check on the stored data based on the first check code, and output the stored data obtained after the data check as first read data, when the mode selection signal indicates that the memory is in an on-die check mode; or directly output the stored data and the first check code as second read data when the mode selection signal indicates that the memory is in an off-die check mode. The first check code in the second read data is employed by an external memory controller to perform a data check operation on the stored data.

In some embodiments, the memory further includes an input/output circuit, configured to: receive the mode selection signal, and serialize the received first read data based on a first burst length and then generate multiple first output data strings to be output to multiple data ports, when the mode selection signal indicates that the memory is in the on-die check mode; or serialize the received second read data based on a second burst length and then generate multiple second output data strings to be output to the multiple data ports, when the mode selection signal indicates that the memory is in the off-die check mode. The first burst length is less than the second burst length.

In some embodiments, each of the first output data strings includes a part of the stored data that is serially output, and each of the second output data strings includes a part of the stored data that is serially output and a part of the first check code.

In some embodiments, the input/output circuit is further configured to: receive an extended function indication signal, and serialize the received second read data and first extended data based on a third burst length and then generate multiple third output data strings to be output to the multiple data ports, when the mode selection signal indicates that the memory is in the off-die check mode and the extended function indication signal indicates that the memory enables an extended function. Each of the third output data strings includes a part of the stored data that is serially output, a part of the first check code, and a part of the first extended data.

In some embodiments, the input/output circuit is further configured to: parallelize a first input data string of a first burst length received from each of the data ports and then generate first write data to be output to the data check circuit, when the mode selection signal indicates that the memory is in the on-die check mode; or parallelize a second input data string of a second burst length received from each of the data ports and then generate second write data to be output to the data check circuit, when the mode selection signal indicates that the memory is in the off-die check mode. The first write data includes to-be-stored data, the second write data includes the to-be-stored data and a corresponding second check code, the first input data string includes a part of the to-be-stored data that is serially input, and the second input data string includes a part of the to-be-stored data that is serially input and a part of the second check code.

In some embodiments, the data check circuit is further configured to: encode the to-be-stored data in the received first write data to generate a corresponding third check code, and respectively store the to-be-stored data and the third check code in the multiple data storage blocks and the check code storage block, when the mode selection signal indicates that the memory is in the on-die check mode; or respectively store the to-be-stored data in the received second write data and the second check code in the multiple data storage blocks and the check code storage block when the mode selection signal indicates that the memory is in the off-die check mode.

In some embodiments, the input/output circuit is further configured to: receive an extended function indication signal, and parallelize a third input data string of a third burst length received from each of the data ports and then generate third write data to be output to the data check circuit, when the mode selection signal indicates that the memory is in the off-die check mode and the extended function indication signal indicates that the memory enables an extended function. The third write data includes the to-be-stored data, the corresponding second check code, and second extended data. The third input data string includes a part of the to-be-stored data that is serially input, a part of the second check code, and a part of the second extended data.

In some embodiments, the memory further includes a data transmission circuit, connected between the data check circuit and the input/output circuit. The data transmission circuit is configured to: transmit the first read data or the second read data from the data check circuit to the input/output circuit, and transmit the first write data or the second write data from the input/output circuit to the data check circuit.

In some embodiments, the input/output circuit includes a data conversion circuit, the data conversion circuit includes multiple data conversion subcircuits in a one-to-one correspondence with the multiple data ports, and each of the data conversion subcircuits includes a serializer and a parallelizer. The serializer is separately coupled to the data transmission circuit and the corresponding data port, and is configured to: serialize, based on the first burst length, a part of the stored data received from the data transmission circuit and then generate the first output data string to be output to the corresponding data port, when the mode selection signal indicates that the memory is in the on-die check mode; or serialize, based on the second burst length, a part of the stored data received from the data transmission circuit and a part of the first check code and then generate the second output data string to be output to the corresponding data port, when the mode selection signal indicates that the memory is in the off-die check mode. The parallelizer is separately coupled to the data transmission circuit and the corresponding data port, and is configured to: parallelize the first input data string received from the corresponding data port and then generate a part of the first write data to be output to the data transmission circuit, when the mode selection signal indicates that the memory is in the on-die check mode; or parallelize the second input data string received from the corresponding data port and then generate a part of the second write data to be output to the data transmission circuit, when the mode selection signal indicates that the memory is in the off-die check mode.

In some embodiments, the input/output circuit further includes a first in first out register and a data driver. The first in first out register is coupled between the data transmission circuit and the data conversion circuit, and is configured to: receive and cache the first read data or the second read data from the data transmission circuit during a read operation performed by the memory; and receive and cache the parallelized first write data or the parallelized second write data from the data conversion circuit during a write operation performed by the memory. The data driver is coupled between the data conversion circuit and the multiple data ports, and is configured to: receive the multiple serialized first output data strings or the multiple serialized second output data strings from the data conversion circuit and drive output to the multiple data ports, during a read operation performed by the memory; and receive the multiple corresponding first input data strings or the multiple corresponding second input data strings through the multiple data ports and drive output to the data conversion circuit, during a write operation performed by the memory.

In some embodiments, the data transmission circuit includes a stored data transmission bus and a check code transmission bus. The stored data transmission bus is configured to transmit the stored data or the to-be-stored data. The check code transmission bus is configured to: receive the mode selection signal, and transmit the first check code or the second check code when the mode selection signal indicates that the memory is in the off-die check mode; or be disabled when the mode selection signal indicates that the memory is in the on-die check mode.

In some embodiments, the data transmission circuit further includes an extended data bus. The extended data bus is configured to: receive the mode selection signal and the extended function indication signal, and transmit the first extended data or the second extended data when the mode selection signal indicates that the memory is in the off-die check mode and the extended function indication signal indicates that the memory is in a state in which the extended function is enabled; otherwise, the extended data bus is disabled.

According to a second aspect, an embodiment of the present disclosure provides a storage device. The storage device includes at least one storage channel, and each of the storage channel includes multiple memories according to the first aspect.

According to a third aspect, an embodiment of the present disclosure provides a memory operation method. A memory includes multiple data storage blocks and a check code storage block. The operation method includes the following steps: Stored data and a corresponding first check code are respectively obtained from the multiple data storage blocks and the check code storage block; a check mode of the memory is determined in response to a mode selection signal; and data check is performed on the stored data based on the first check code and the stored data obtained after the data check is output as first read data, when the mode selection signal indicates that the memory is in an on-die check mode; or the stored data and the first check code are directly output as second read data when the mode selection signal indicates that the memory is in an off-die check mode. The first check code in the second read data is employed by an external memory controller to perform a data check operation on the stored data.

In some embodiments, the operation method further includes the following steps: The first read data or the second read data is output from the memory through multiple data ports after being serialized. The first read data is serialized based on a first burst length, and then multiple first output data strings to be output through the multiple data ports are generated, when the memory is in the on-die check mode; or the second read data is serialized based on a second burst length, and then multiple second output data strings to be output through the multiple data ports are generated, when the memory is in the off-die check mode; the first burst length is less than the second burst length.

In some embodiments, after the stored data and the first check code are directly output as the second read data, the operation method further includes the following steps: It is determined whether an extended function of the memory is enabled; and the second read data and first extended data are serialized based on a third burst length, and then multiple third output data strings to be output through multiple data ports are generated, if the memory is in the off-die check mode and the extended function is enabled. Each of the third output data strings includes a part of the stored data that is serially output, a part of the first check code, and a part of the first extended data.

According to a fourth aspect, an embodiment of the present disclosure provides a memory operation method. The operation method includes the following steps: A check mode of the memory is determined in response to a mode selection signal; and a first input data string of a first burst length received from each of data ports is parallelized, and then first write data is generated, when the mode selection signal indicates that the memory is in an on-die check mode; or a second input data string of a second burst length received from each of data ports is parallelized, and then second write data is generated, when the mode selection signal indicates that the memory is in an off-die check mode. The second burst length is greater than the first burst length, the first write data includes to-be-stored data, the second write data includes the to-be-stored data and a corresponding second check code, the first input data string includes a part of the to-be-stored data that is serially input, and the second input data string includes a part of the to-be-stored data that is serially input and a part of the second check code.

In some embodiments, the memory includes multiple data storage blocks and a check code storage block, and the operation method further includes the following steps: The to-be-stored data in the received first write data is encoded to generate a corresponding third check code, and the to-be-stored data and the third check code are respectively stored in the multiple data storage blocks and the check code storage block, when the memory is in the on-die check mode; or the to-be-stored data in the received second write data and the second check code are respectively stored in the multiple data storage blocks and the check code storage block, when the memory is in the off-die check mode.

In some embodiments, when the mode selection signal indicates that the memory is in the off-die check mode, the operation method further includes the following steps: It is determined whether an extended function of the memory is enabled; and a third input data string of a third burst length received from each of the data ports is parallelized, and then third write data is generated, if the memory is in the off-die check mode and the extended function is enabled. The third write data includes the to-be-stored data, the corresponding second check code, and second extended data, and the third input data string includes a part of the to-be-stored data that is serially input, a part of the second check code, and a part of the second extended data.

### BRIEF DESCRIPTION OF DRAWINGS

One or more embodiments are described by way of example with the figures in the accompanying drawings corresponding to the one or more embodiments. These example descriptions do not constitute a limitation on the embodiments. Elements with the same reference numerals in the accompanying drawings are similar elements, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1A and FIG. 1B are schematic structural diagrams of a memory according to an embodiment of the present disclosure;

FIG. 2A to FIG. 2H are schematic structural diagrams of another memory according to an embodiment of the present disclosure;

FIG. 3A to FIG. 3D are schematic configuration diagrams of an input data string/output data string employed in an embodiment of the present disclosure;

FIG. 4A and FIG. 4B are schematic structural diagrams of still another memory according to an embodiment of the present disclosure;

FIG. 5 is a schematic structural diagram of an input/output circuit according to an embodiment of the present disclosure;

FIG. 6 is a schematic structural diagram of a data conversion circuit according to an embodiment of the present disclosure;

FIG. 7A to FIG. 7D are schematic structural diagrams of a data conversion subcircuit and a data transmission circuit according to an embodiment of the present disclosure;

FIG. 8A and FIG. 8B are signal timing diagrams corresponding to a data conversion subcircuit according to an embodiment of the present disclosure;

FIG. 9 is a schematic structural diagram of a storage device according to an embodiment of the present disclosure;

FIG. 10 is a schematic flowchart of a memory operation method according to an embodiment of the present disclosure;

FIG. 11 is another schematic flowchart of a memory operation method according to an embodiment of the present disclosure;

FIG. 12 is a schematic flowchart of another memory operation method according to an embodiment of the present disclosure; and

FIG. 13 is another schematic flowchart of another memory operation method according to an embodiment of the present disclosure.

### DESCRIPTION OF EMBODIMENTS

Now, example implementations are more comprehensively described with reference to the accompanying drawings. However, the example implementations can be implemented in multiple forms and should not be construed as being limited to the examples described herein. Instead, these implementations are provided to make the present disclosure more comprehensive and complete, and convey the concept of the example implementations comprehensively to a person skilled in the art. The described features, structures, or characteristics may be properly combined in one or more implementations. In the following description, many specific details are provided to give a full understanding of the implementations of the present disclosure. However, a person skilled in the art will be aware that one or more of the specific details may be omitted by practicing the technical solutions of the present disclosure, or another method, component, apparatus, step, or the like may be employed. In other cases, well-known technical solutions are not detailed or described to avoid overshadowing the aspects of the present disclosure and to prevent any ambiguity.

The terms "first", "second", and the like in the specification, claims, and accompanying drawings of the present disclosure are intended to distinguish between similar or same objects or entities, and do not necessarily indicate a specific order or sequence, unless otherwise noted. It should be understood that the terms employed in such a manner are interchangeable under appropriate circumstances, for example, can be implemented in an order other than those given in the illustrations or descriptions of the embodiments of the present disclosure.

In addition, the accompanying drawings are merely schematic diagrams of the present disclosure, and the same reference numerals in the figures represent the same or similar parts, and therefore, repeated descriptions thereof are omitted. Some block diagrams shown in the accompanying drawings are functional entities and may not necessarily correspond to physically or logically independent entities. These functional entities may be implemented in a form of software, or these functional entities are implemented in one or more hardware modules or integrated circuits, or these functional entities are implemented in different networks and/or processor apparatuses and/or microcontroller apparatuses.

It should be noted that brief description of terms in the present disclosure is merely intended to facilitate understanding of the implementations described below, and is not intended to limit the implementations of the present disclosure. Unless otherwise specified, these terms should be understood based on ordinary and common meanings thereof. In addition, the terms "comprise", "include", "have", and any variants thereof are intended to cover non-exclusive inclusion. For example, a product or a device including a series of components is not necessarily limited to the components that are expressly listed, and may include another component that is not expressly listed or is inherent to the product or the device.

In a related technology, to improve data integrity and system reliability, an error checking and correction (Error Checking and Correction, ECC) function is added to a memory. There are multiple ECC implementations employed in a current memory product, such as On-Die ECC (on-die ECC), Link ECC (link ECC), and Side Band ECC (sideband ECC). Although the foregoing implementations can provide data protection in a memory system, each implementation has a potential disadvantage. For the On-Die ECC, an ECC logic circuit needs to be integrated into a memory chip and a memory array for checking data needs to be configured, increasing an area and additional costs of the memory chip. However, the On-Die ECC cannot provide any protection for a data error occurring on a data transmission link (a transmission link between the memory and the controller and a data transmission path inside the memory). Therefore, the On-Die ECC needs to work with another ECC implementation (e.g., Link ECC and Side Band ECC) to implement data protection for the entire data transmission link. For the Link ECC, additional ECC processing needs to be performed on the data transmission link, which may increase a delay of data transmission and affect overall performance of the system. In addition, the link ECC does not provide any protection for a data error occurring on the memory array. For the Side Band ECC implementation, an additional memory particle needs to be added to store ECC data, greatly increasing costs of a storage system product.

To resolve the foregoing problems of the ECC solutions in an existing memory, an embodiment of the present disclosure provides a memory. The memory includes the following steps: multiple data storage blocks and a check code storage block; and a data check circuit, configured to: respectively obtain stored data and a corresponding first check code from the multiple data storage blocks and the check code storage block, and determine, in response to a received mode selection signal, whether to perform a data check operation. The data check circuit is further configured to: perform data check on the stored data based on the first check code, and output the stored data obtained after the data check as first read data, when the mode selection signal indicates that the memory is in an on-die check mode; or directly output the stored data and the first check code as second read data when the mode selection signal indicates that the memory is in an off-die check mode. The first check code in the second read data is employed by an external memory controller to perform a data check operation on the stored data. In this way, a data check circuit that may select an on-die check mode and an off-die check mode is disposed in a memory, so that a check mode can be flexibly configured to improve utilization of an on-die storage resource and increase diversity of a data protection solution. When an error risk of a memory cell array of a memory chip is higher, selection of the on-die check mode may be configured, so as to employ a check code stored on a die to check and correct a data error occurring in a data storage process on a memory chip. When an error risk of a data transmission link in a storage system is higher, selection of the off-die check mode may be configured, so as to directly send a check code stored on a die and stored data to an external memory controller, so that the memory controller can employ the check code to check and correct a data error occurring on a complete data transmission link in the storage system. Therefore, according to the memory provided in the embodiments of the present disclosure, compatibility with a data check function performed on the memory chip and an off-die data check function performed by the controller may be implemented by employing the same check code storage block, thereby more efficiently employing an on-die check code storage block resource, and saving additional storage resource consumption incurred by employing another ECC solution (e.g., the side band ECC) for checking and correcting an error on the entire data transmission link.

The embodiments of the present disclosure are described in detail below with reference to the accompanying drawings. However, it may be understood by a person of ordinary skill in the art that in the embodiments of the present disclosure, many technical details are provided to enable readers to better understand the present disclosure. However, the technical solutions claimed in the present disclosure may be implemented even without these technical details and various variations and modifications made based on the following embodiments.

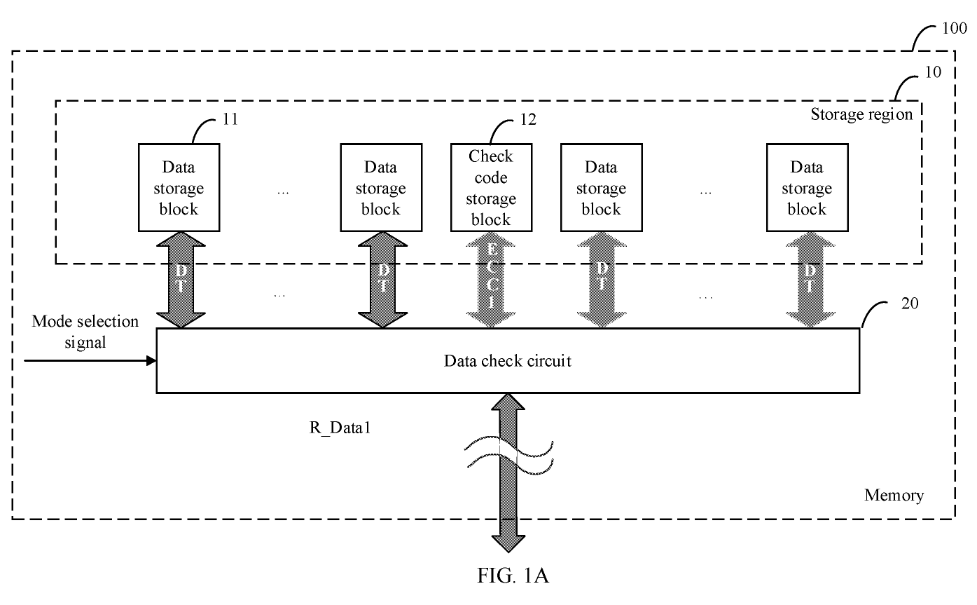

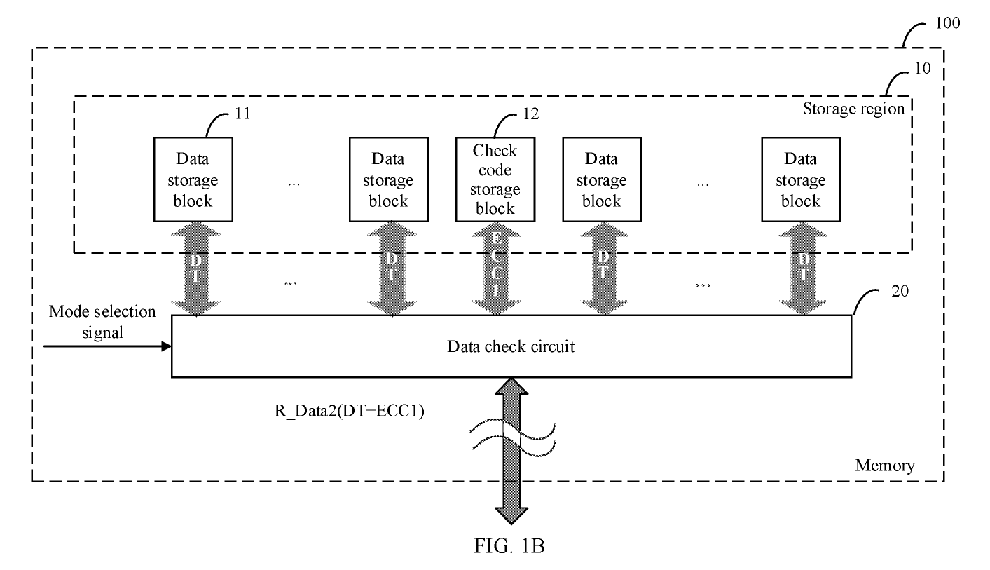

In an embodiment of the present disclosure, reference is made to FIG. 1A and FIG. 1B, which are schematic structural diagrams of a memory 100 according to an embodiment of the present disclosure. As shown in FIG. 1A and FIG. 1B, the memory 100 includes: multiple data storage blocks 11 and a check code storage block 12; and a data check circuit 20, configured to: respectively obtain stored data DT and a corresponding first check code ECC1 from the multiple data storage blocks 11 and the check code storage block 12, and determine, in response to a received mode selection signal, whether to perform a data check operation. The data check circuit 20 is further configured to: perform data check on the stored data DT based on the first check code ECC1, and output the stored data DT obtained after the data check as first read data R_Data1, when the mode selection signal indicates that the memory 100 is in an on-die check mode; or directly output the stored data DT and the first check code ECC1 as second read data R_Data2 when the mode selection signal indicates that the memory 100 is in an off-die check mode. The first check code ECC1 in the second read data R_Data2 is employed by an external memory controller to perform a data check operation (as shown in FIG. 1B) on the stored data DT.

The mode selection signal having a first level indicates that the memory 100 is in the on-die check mode, and the mode selection signal having a second level indicates that the memory 100 is in the off-die check mode. Herein, the first level may be a high level (logic "1"), and correspondingly, the second level is a low level (logic "0"). Alternatively, the first level may be a low level (logic "0"), and correspondingly, the second level is a high level (logic "1"). This is not specifically limited herein.

As shown in FIG. 1A and FIG. 1B, the memory 100 includes a storage region 10 and a peripheral circuit region. Functional circuits such as the data check circuit 20 are all disposed in the peripheral circuit region. The storage region 10 is configured to store data, and the storage region 10 may include multiple banks (not shown in the figures). Each bank may include multiple sections (not shown in the figures) obtained through division in a bit line direction. Each section includes multiple data storage blocks 11 and a check code storage block 12. Each section further includes multiple sense amplifier arrays (not shown in the figures). Each of the sense amplifier arrays is disposed between storage blocks. Each storage block may include multiple memory cells.

Still referring to FIG. 1A and FIG. 1B, a data check circuit 20 that may select an on-die check mode and an off-die check mode is disposed in the memory 100 provided in this embodiment of the present disclosure. By configuring the data check mode, the data check circuit 20 may flexibly select how to employ and transmit the first check code ECC1 and the stored data DT. Specifically, as shown in FIG. 1A, when the mode selection signal indicates that the memory 100 is configured to be in the on-die check mode, the first check code ECC1 is configured to provide data protection for an internal data storage process of the memory. To be specific, the data check circuit 20 directly performs error checking and error correction on the stored data DT based on the first check code ECC1. In this case, the first check code ECC1 has been employed by the data check circuit 20 and a data check function is completed, and output is not required. The data check module 20 outputs only the stored data DT obtained after the data check as the first read data R_Data1. As shown in FIG. 1B, when the mode selection signal indicates that the memory 100 is in the off-die check mode, the first check code ECC1 is configured to provide data protection for a complete data transmission link of the storage system. To be specific, the data check circuit 20 no longer performs an on-die data check operation, but directly outputs the stored data DT and the first check code ECC1 as the second read data R_Data2. In this case, the output first check code ECC1 is received by an external memory controller to complete a data check operation on the stored data DT. In this embodiment of the present disclosure, the memory flexibly configures the data check mode of the data check circuit, so as to implement compatibility with an on-die data check function and an off-die data check function by employing the same check code storage block resource, thereby improving utilization of an on-die check code storage resource, increasing diversity of a data protection solution, and further saving additional storage resource consumption incurred by employing an off-die data check ECC solution.

Quantities of memory cells (bit widths) in the check code storage block 12 and the data storage block 11 may be set to be the same, or may be set to be different. Specifically, a data proportion between the stored data DT and the corresponding first check code ECC1 is determined based on an encoding manner for data check employed in the storage system, and further, the quantity of memory cells in the check code storage block 12 is selected and set. For example, a configuration of the DDR5 memory is a data bus width X8 or a burst length (Burst Length, BL) 16. Eight data storage blocks are set in each data segment. When a Hamming code is employed as a data check manner, pre-obtained stored data DT is 8(mat)*16(BL)=128b, and a first check code that needs to be pre-obtained corresponding to the 128b stored data is 8b. In this case, a bit width of the check code storage block 12 may be set to half of the data storage block 1.

It should be noted that structures of the memory 100 shown in FIG. 1A and FIG. 1B are the same. In the present disclosure, only data exchange between component circuits is shown in FIG. 1A and FIG. 1B respectively when the memory 100 performs read access operations in different check modes.

In some embodiments of the present disclosure, a value of the mode selection signal is determined by a configuration parameter in a mode register of the memory, and the memory controller may modify the configuration parameter in the mode register of the memory by employing a mode register read/write command.

In some embodiments of the present disclosure, multiple check code storage blocks 12 may be disposed in each section of the memory, so as to increase a quantity of first check codes ECC1 to improve an error correction capability of the memory.

In some embodiments of the present disclosure, an improvement is made on the basis of an original on-die ECC circuit of the memory, and a function of selecting an on-die check mode of the memory is added to obtain a data check circuit in the present disclosure. When the on-die check mode is selected for execution, the data check circuit enables the original on-die ECC circuit, performs data check (that is, error checking and/or error correction) on the stored data DT based on the first check code ECC1 obtained from the check code storage block, and outputs the Data obtained after the data check as the first read data R_Data1. When the off-die check mode is selected for execution, the data check circuit disables a data check function of the original on-die ECC circuit, that is, bypasses the original on-die ECC circuit, and the data check circuit outputs the obtained stored data DT and the first check code ECC1 as the second read data R_Data2.

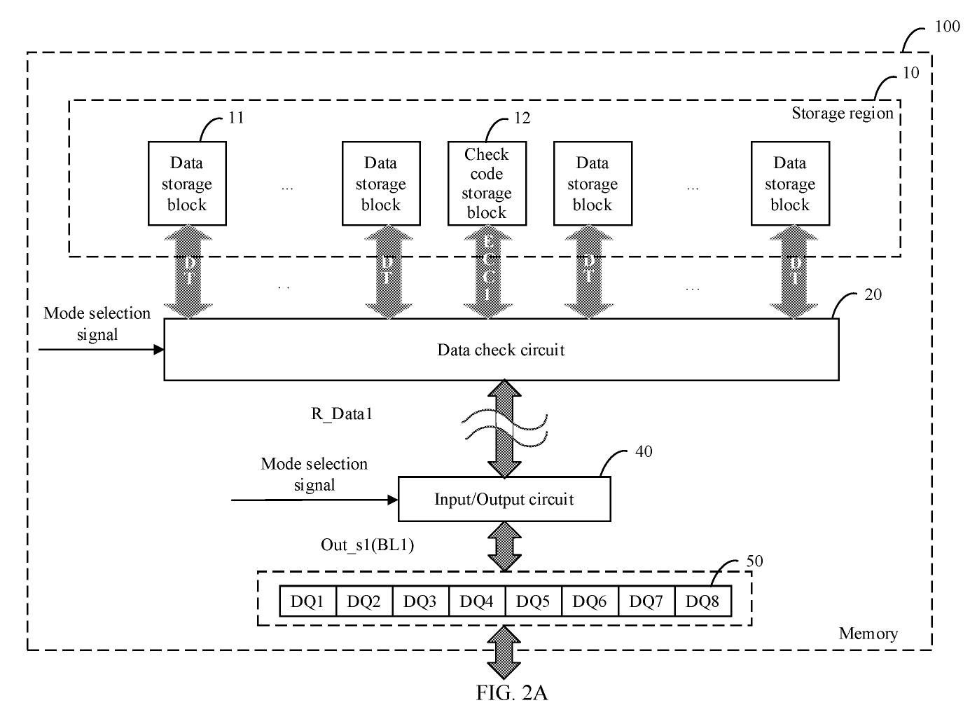

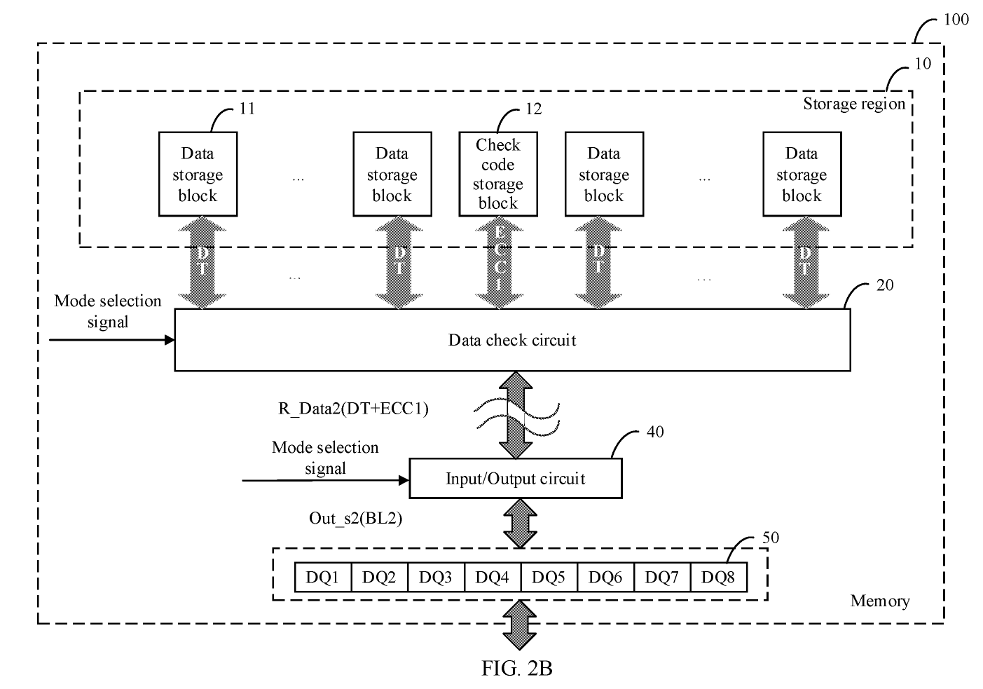

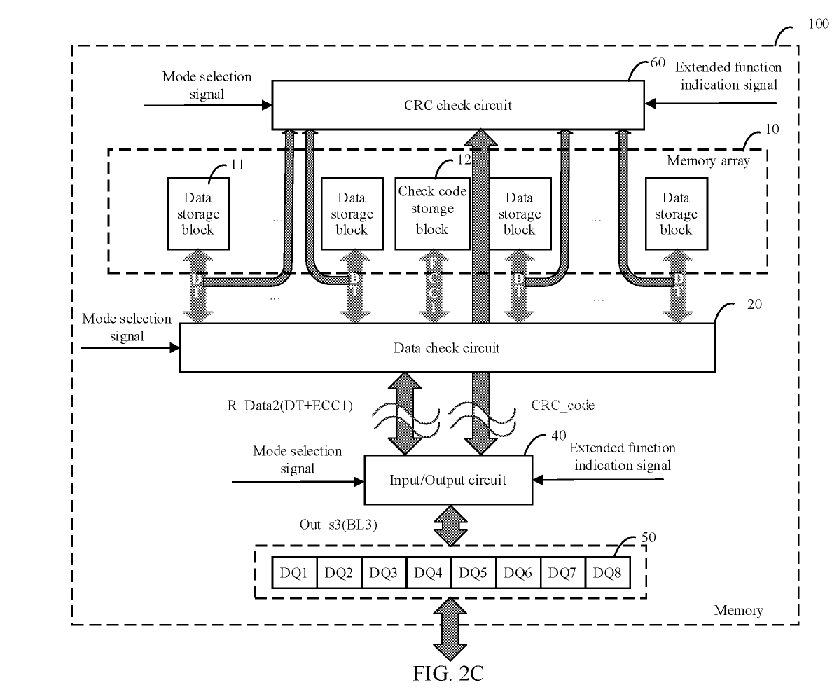

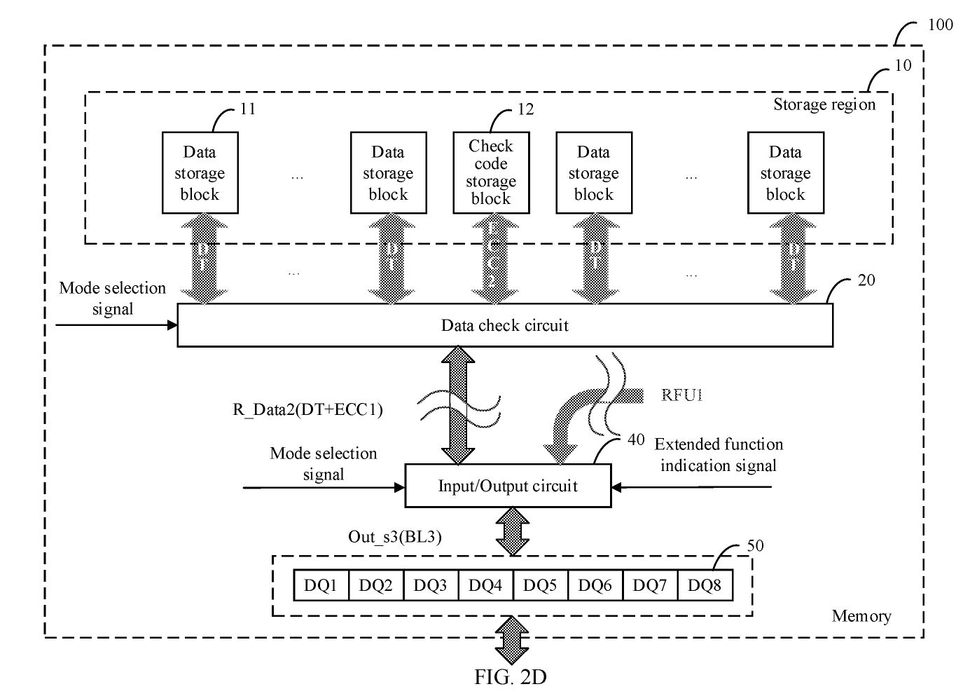

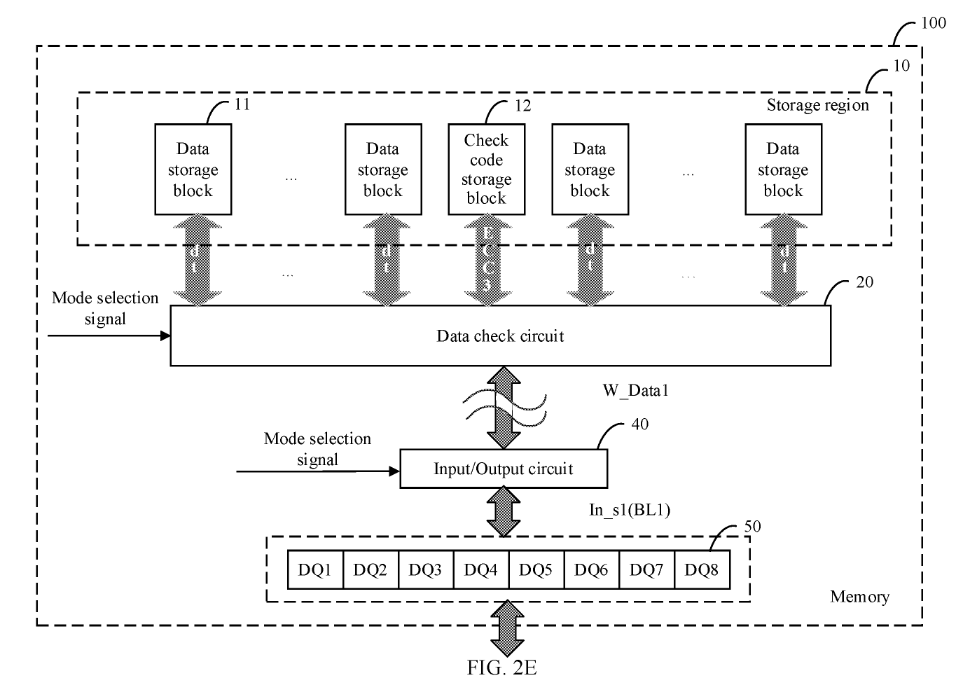

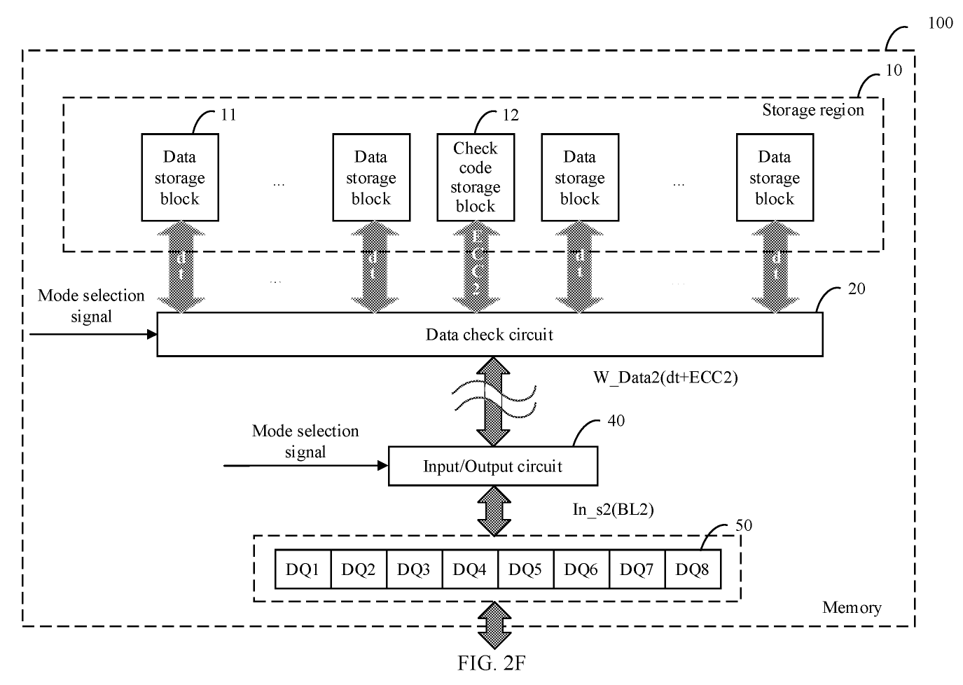

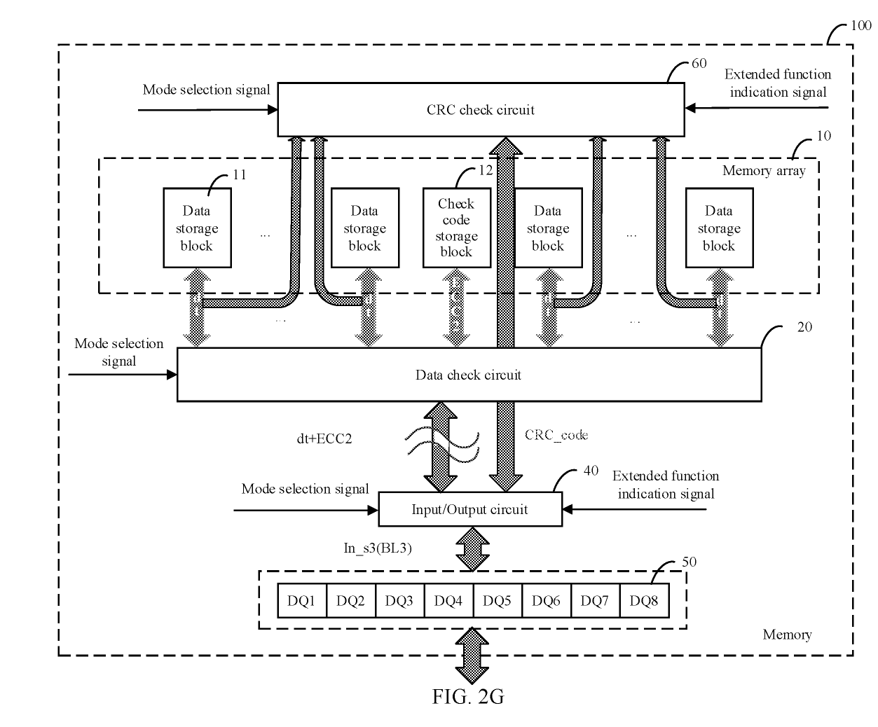

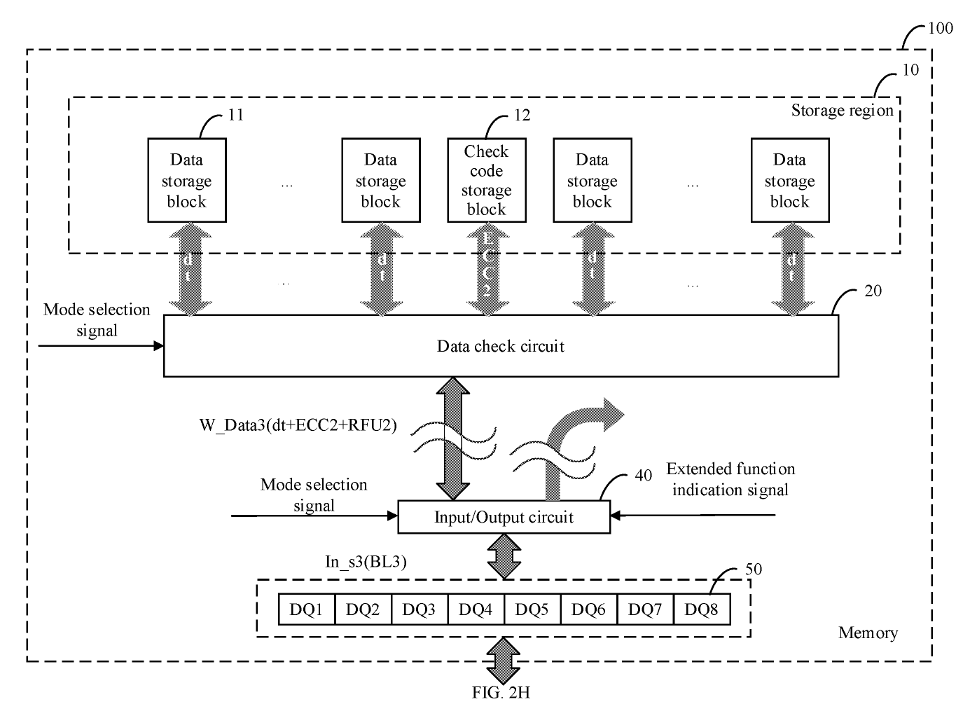

Reference is made to FIG. 2A to FIG. 2C, which are schematic structural diagrams of another memory according to an embodiment of the present disclosure. As shown in FIG. 2A, the memory 100 further includes an input/output circuit 40, configured to: receive the mode selection signal, and serialize the received first read data R_Data1 based on a first burst length BL1 (Burst Length 1) and then generate multiple first output data strings Out_s1 (as shown in FIG. 2A) to be output to multiple data ports (DQ) 50, when the mode selection signal indicates that the memory 100 is in the on-die check mode; or serialize the received second read data R_Data2 based on a second burst length BL2 (Burst Length 2) and then generate multiple second output data strings Out_s2 (as shown in FIG. 2B) to be output to the multiple data ports 50, when the mode selection signal indicates that the memory is in the off-die check mode. The first burst length BL1 is less than the second burst length BL2.

In this embodiment of the present disclosure, when the memory 100 is respectively in the on-die check mode and the off-die check mode, an amount of parallel data received by the input/output circuit 40 varies, and a quantity of data ports 50 in the memory 100 is preset and kept unchanged. Therefore, in a case in which no additional data port resource is added, after the input/output circuit 40 serializes the received parallel data, a data amount (a burst length BL) of serial data that needs to be transmitted through each of the data ports 50 also varies. Specifically, 128b stored data, 8b first check code data, and eight data ports (X8) are taken as examples for description. In the on-die check mode, as shown in FIG. 2A, the first read data R_Data1 received by the input/output circuit 40 includes only the 128b stored data DT obtained after the error checking and error correction, and the input/output circuit 40 only needs to serialize the 128b stored data DT obtained after the error checking and error correction, to obtain eight first output data strings Out_s1 corresponding to eight data ports 50. A serial data length of each of the first output data strings Out_s1 is 128/8=16, that is, a corresponding first burst length BL1 is 16. However, in the off-die check mode, as shown in FIG. 2B, the second read data R_Data2 received by the input/output circuit 40 includes not only the 128b stored data DT, but also the 8b first check code ECC1 that needs to be transmitted externally. After the input/output circuit 40 serializes the second read data R_Data2 (128b Data+8b ECC1), eight second output data strings Out_s2 corresponding to the eight data ports 50 are obtained. A serial data length of each of the second output data string Out_s2 is (128+8)/8=17, that is, a corresponding second burst length BL2 is 17. Therefore, the memory 100 in the off-die check mode needs to additionally transmit the 8b first check code ECC1 through the eight data ports 50. To be specific, each of the data ports 50 needs to additionally transmit the 1b data, and a second burst length of the second output data string Out_s2 correspondingly transmitted by the data port 50 is greater than the first burst length BL1 corresponding to the first output data string Out_s1.

It should be noted that the input/output circuit 40 in this embodiment of the present disclosure sets at least two data processing modes of different burst lengths, so as to respectively match processing requirements for different data (the first read data R_Data1 and the second read data R_Data2 with different data amounts that are output by the data check circuit 20) received in the two data check modes.

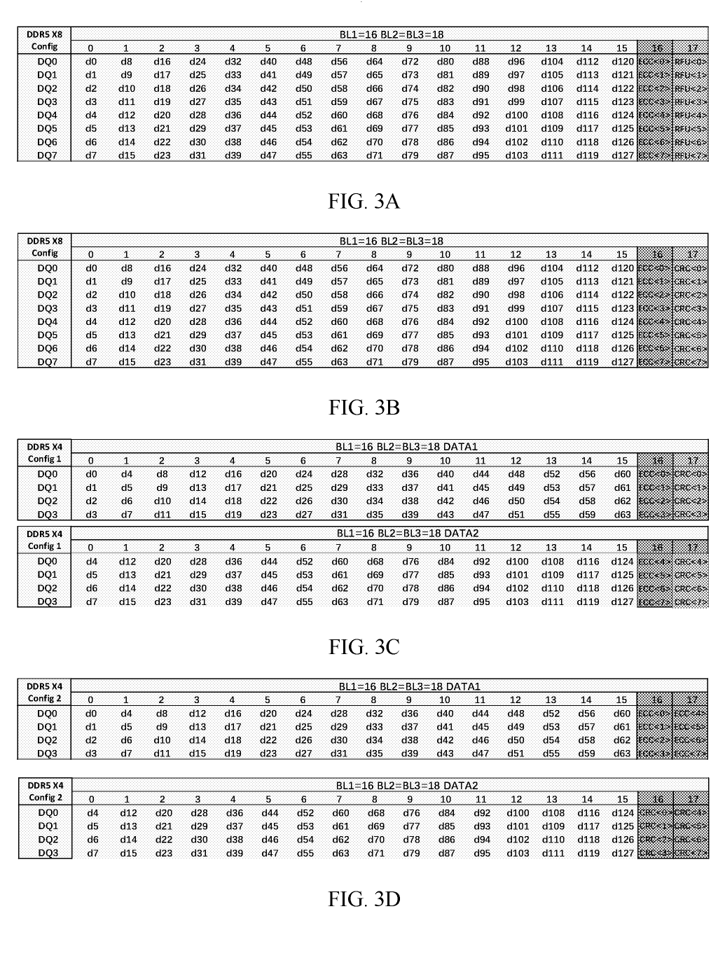

In an embodiment of the present disclosure, referring to FIG. 2A, FIG. 2B, and FIG. 3A, each of the first output data strings Out_s1 includes a part of the stored data DT that is serially output, and each of the second output data strings Out_s2 includes a part of the stored data DT that is serially output and a part of the first check code ECC1.

It should be noted that the first burst length BL1 is related to a specification of the memory and a data bus bandwidth configuration, and the second burst length BL2 is set based on factors such as the first burst length BL1, a quantity of first check codes ECC1 that need to be additionally transmitted, and a data bus width. The second burst length BL2 may be set to just meet a transmission requirement for the first check code ECC1, so as to shorten a transmission time of serial data. Alternatively, the second burst length BL2 may be set to be slightly greater than a transmission requirement for the first check code ECC1, so as to reserve an additional location in the second output data string Out_s2 to meet a transmission requirement for data of another extended function. Specifically, the X4/X8/X16/X32… configuration of the memory refers to a data bus bandwidth, and may alternatively be understood as a quantity of data ports for parallel input/output of the memory. The burst length BL configuration of the memory refers to a quantity of data blocks continuously transmitted during one access to the memory, and may alternatively be understood as an amount of data that is continuously and serially input/output by each of the data ports in the memory. The burst length and the data bus bandwidth of the memory jointly affect data transmission efficiency and speed of the memory. A data transmission situation in which the DDR5 performs a read operation is described with reference to FIG. 2A to FIG. 2C and FIG. 3A. As shown in FIG. 3A, the memory 100 has an X8 data bus width configuration (that is, the memory 100 has eight data ports 50 for parallel input/output), and 128b stored data needs to be transmitted during a single read/write of the memory 100. When the memory 100 is in the on-die check mode, as shown in FIG. 2A, the first burst length BL1 =128b/8(X8) =16, and all bits Out_s1<0:15> in the first output data string Out_s1 correspondingly transmitted by each of the data ports are configured to transmit the stored data. When the memory 100 is in the off-die data check mode, as shown in FIG. 2B, the first check code ECC1 that needs to be additionally transmitted is 8b in total, and each of the data ports 50 needs to additionally transmit only 1b data. Theoretically, a burst length BL may be set to any value greater than or equal to 17. However, because the DDR5 employs dual-edge data sampling, an odd-numbered burst length is not conducive to data transmission between the memory and the controller, and the burst length BL needs to be set to an even number. Therefore, the second burst length BL2 is correspondingly set to 18. In this case, first 16 bits Out_s2<0:15> in the second output data string Out_s2 correspondingly transmitted by each of the data ports are configured to transmit the stored data DT, the 17th bit BL2<16> is configured to transmit the first check code ECC1, and the 18th bit BL2<17> is configured to transmit extended data RFU corresponding to another extended function. It should be noted herein that, for a memory product of another specification, e.g., a DDR4 chip, the second burst length BL2 corresponding to the second output data string Out_s2 under the same circumstance may be set to 17. In this case, the second output data string Out_s2<0:16> includes only a part of the stored data DT and a part of the first check code ECC1.

Reference is still made to FIG. 3C and FIG. 3D, which are schematic diagrams of two input/output data configurations according to an embodiment of the present disclosure. For an X4 data bus width configuration of the memory 100, 64b stored data needs to be transmitted for single read/write access. Compared with the X8 configuration, the stored data transmitted is reduced by half. When the memory 100 is in the on-die check mode, the first burst length BL1=64b/4(X4) =16, and like the X8 configuration, all bits Out_s1<0:15> in the first output data string Out_s1 correspondingly transmitted by each of the data ports are configured to transmit the stored data. However, in the off-die data check mode, the stored data (2*64b stored data) for two times of read/write access corresponds to the same 8b data of the first check code ECC1. In other words, the first check code ECC1 that needs to be additionally transmitted for the two times of read/write access is 8b in total, and the second burst length BL2 is correspondingly set to 18. In this case, there are two specific data configuration manners. In a first configuration manner, as shown in FIG. 3C, the 17th bit BL2<16> in the second output data string Out_s2 output for the first read is configured to transmit the 4b first check code ECC1(ECC<0:3>), and the 18th bit BL2<17> is configured to transmit 4b extended data (CRC<0:3>) corresponding to another extended function; the 17th bit BL2<16> in the second output data string Out_s2 output for the second read is configured to transmit the other 4b first check code ECC1(ECC<4:7>), and the 18th bit BL2<17> is configured to transmit the other 4b extended data (CRC<4:7>) corresponding to another extended function. In a second configuration manner, as shown in FIG. 3D, the 17th and 18th bits BL2<16:17> in the second output data string Out_s2 output for the first read are both configured to transmit the 8b first check code ECC1(ECC<0:7>), and the 17th and 18th bits BL2<16:17> in the second output data string Out_s2 output for the second read are both configured to transmit the 8b extended data (CRC<0:7>) corresponding to another extended function. A specific X4 data configuration manner to be employed may be configured based on a special bit (CA10) in a read command or a parameter in a mode register.

In an embodiment of the present disclosure, still referring to FIG. 2C and FIG. 3A, the input/output circuit 40 is further configured to: receive an extended function indication signal, and serialize the received second read data R_Data2 and first extended data RFU1 based on a third burst length BL3 and then generate multiple third output data strings Out_s3 to be output to the multiple data ports 50, when the mode selection signal indicates that the memory 100 is in the off-die check mode and the extended function indication signal indicates that the memory 100 enables an extended function. Each of the third output data strings Out_s3 includes a part of the stored data DT that is serially output, a part of the first check code ECC1, and a part of the first extended data RFU1.

The extended function indication signal having a third level indicates that the extended function of the memory 100 is enabled, and the extended function indication signal having a fourth level indicates that the extended function of the memory 100 is not enabled. Herein, the third level may be a high level (logic "1"), and correspondingly, the fourth level is a low level (logic "0"). Alternatively, the third level may be a low level (logic "0"), and correspondingly, the fourth level is a high level (logic "1"). This is not specifically limited herein.

It should be noted that, as shown in FIG. 2D and FIG. 3B to FIG. 3D, the extended function may be a cyclic redundancy check (CRC) function, and the corresponding first extended data RFU1 may be cyclic redundancy check data CRC_code. Alternatively, the extended function may be another function performed in the memory. In the present disclosure, the CRC function serving as the extended function is merely taken as an example for description, and does not constitute a limitation on this embodiment of the present disclosure.

As shown in FIG. 2D and FIG. 3B, the input/output circuit 40 transmits the second read data R_Data2 and the cyclic redundancy check data CRC_code (that is, the first extended data). The first 16 bits Out_s2<0:15> in the third output data string Out_s3 correspondingly transmitted by each of the data ports are configured to transmit the stored data DT, the 17th bit BL2<16> is configured to transmit the first check code ECC1, and the 18th bit BL2<17> is configured to transmit the cyclic redundancy check data CRC_code corresponding to the cyclic redundancy check (CRC) function.

Herein, the third burst length BL3 and the second burst length BL2 may be set to be the same. As shown in FIG. 3A to FIG. 3D, BL2=BL3=18. In this case, the input/output circuit 40 only needs to implement data conversion modes of two burst lengths, which can simplify a circuit structure of the input/output circuit 40, thereby helping reduce power consumption and reduce an area. The third burst length BL3 and the second burst length BL2 may alternatively be set to be different. For example, for the DDR4 product, the BL2 may be set to 17, and the BL3 may be set to 18. When the extended function does not need to be enabled, setting a smaller second burst length BL2 helps shorten a data output time.

It should be noted that when the memory is in the on-die check mode or the extended function of the memory is not enabled, the extended data does not need to be output externally through the data port 50, and the input/output circuit 40 does not need to process the extended data. For example, the cyclic redundancy check data CRC_code does not need to be received and serialized. In this case, the circuit module that processes the extended data in the input/output circuit 40 may be turned off or disabled, thereby increasing a data processing speed of the input/output circuit 40 and reducing power consumption of the input/output circuit.

In an embodiment of the present disclosure, still referring to FIG. 2D, the memory 100 further includes a CRC check circuit 60, configured to: obtain stored data DT from multiple data storage blocks 11, and generate and output cyclic redundancy check data CRC_code corresponding to the stored data DT when the mode selection signal indicates that the memory 100 is in the off-die check mode and the extended function indication signal indicates that the memory enables the extended function.

In an embodiment of the present disclosure, when the memory 100 is in the on-die check mode or the extended function is not enabled, the input/output circuit 40 does not receive and process other data (the first check code ECC1 and the cyclic redundancy check data CRC_code) except the stored data DT. In this case, the CRC check circuit 60 may be disabled, so that the CRC check circuit does not receive and process the stored data DT, thereby saving internal power consumption of the memory.

The check code employed by the CRC check circuit 60 may be designed based on a location that can be occupied by data of the extended function in the third output data string Out_s3. FIG. 3B is taken as an example for description. A total of eight bits in eight third output data strings Out_s3 corresponding to eight data ports may be configured as the cyclic redundancy check data CRC_code. In other words, the 128b stored data corresponds to the 8b cyclic redundancy check data, and an ATM-4 HEC encoding manner may be employed.

It should be noted that FIG. 2A to FIG. 2D respectively show functions to be completed by component circuits and data exchange between the component circuits when the memory 100 performs read access operations in different check modes.

The component circuits such as the multiple data ports 50, the input/output circuit 40, the data transmission circuit 30, and the data check circuit 20 in the memory 100 provided in this embodiment of the present disclosure can all perform a bidirectional data processing and transmission function. In other words, the foregoing component circuits in the memory 100 support not only a read access operation but also a write access operation. With reference to FIG. 2E to FIG. 2H, and FIG. 3A to FIG. 3D, the following describes functions to be completed by component circuits and data exchange between the component circuits when the memory 100 provided in this embodiment of the present disclosure performs write access operations in different check modes.

In an embodiment of the present disclosure, as shown in FIG. 2E and FIG. 2F, when the memory 100 performs a write operation, the input/output circuit 40 is further configured to: parallelize a first input data string In_s1 of a first burst length BL1 received from each of the data ports 50 and then generate first write data W_Data1 to be output to the data check circuit 20, when the mode selection signal indicates that the memory 100 is in the on-die check mode, as shown in FIG. 2E; or parallelize a second input data string In_s2 of a second burst length BL2 received from each of the data ports 50 and then generate second write data W_Data2 to be output to the data check circuit 20, when the mode selection signal indicates that the memory 100 is in the off-die check mode, as shown in FIG. 2F. The first write data W_Data1 includes to-be-stored data dt, the second write data W_Data2 includes the to-be-stored data dt and a corresponding second check code ECC2, the first input data string In_s1 includes a part of the to-be-stored data dt that is serially input, and the second input data string In_s2 includes a part of the to-be-stored data dt that is serially input and a part of the second check code ECC2.

In an embodiment of the present disclosure, still referring to FIG. 2E and FIG. 2F, the data check circuit 20 is further configured to: encode the to-be-stored data dt in the received first write data W_Data1 to generate a corresponding third check code ECC3, and respectively store the to-be-stored data dt and the third check code ECC3 in the multiple data storage blocks 11 and the check code storage block 12, when the mode selection signal indicates that the memory 100 is in the on-die check mode; or respectively store the to-be-stored data dt in the received second write data W_Data2 and the second check code ECC2 in the multiple data storage blocks 11 and the check code storage block 12 when the mode selection signal indicates that the memory 100 is in the off-die check mode.

In an embodiment of the present disclosure, still referring to FIG. 2G and FIG. 2H, the input/output circuit 40 is further configured to: receive an extended function indication signal, and parallelize a third input data string In_s3 of a third burst length BL3 received from each of the data ports 50 and then generate third write data W_Data3 to be output to the data check circuit 20, when the mode selection signal indicates that the memory 100 is in the off-die check mode and the extended function indication signal indicates that the memory 100 enables an extended function.

The third write data W_Data3 includes the to-be-stored data dt, the corresponding second check code ECC2, and second extended data RFU2, and the third input data string In_s3 includes a part of the to-be-stored data dt that is serially input, a part of the second check code ECC2, and a part of the second extended data RFU2.

As described above, the third burst length BL3 and the second burst length BL2 may be set to be the same, or may be set to be different.

It should be noted that when the memory is in the on-die check mode or the extended function of the memory is not enabled, the externally input extended data does not need to be received through the data port 50, and the input/output circuit 40 does not need to process the extended data. For example, the cyclic redundancy check data CRC_code does not need to be received and parallelized. In this case, the circuit module that processes the extended data in the input/output circuit 40 may be turned off or disabled, thereby increasing a data processing speed of the input/output circuit 40 and reducing power consumption of the input/output circuit.

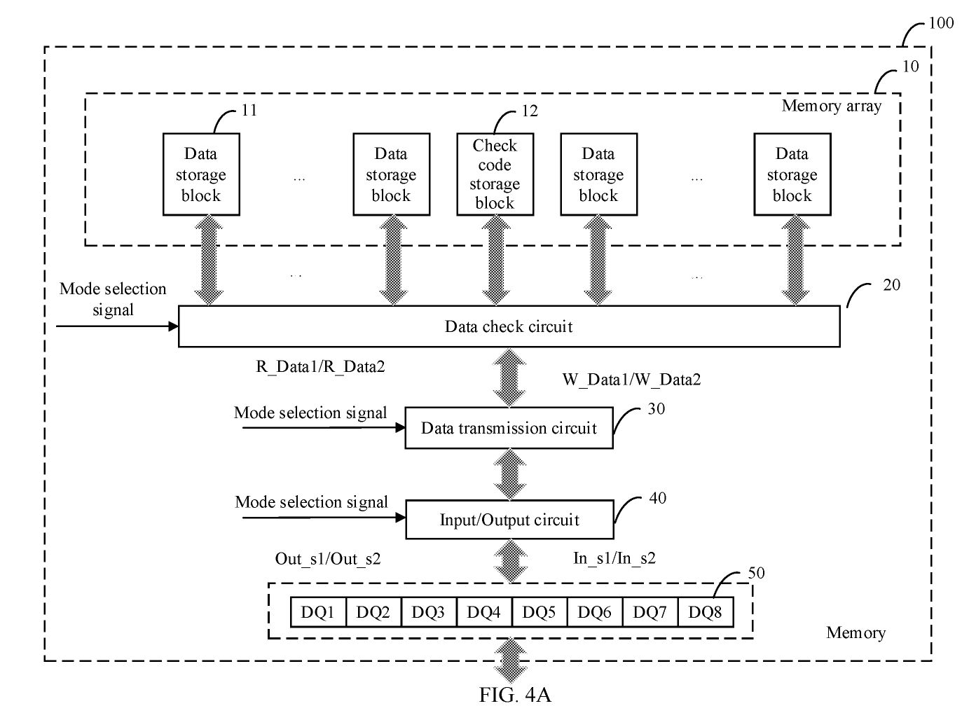

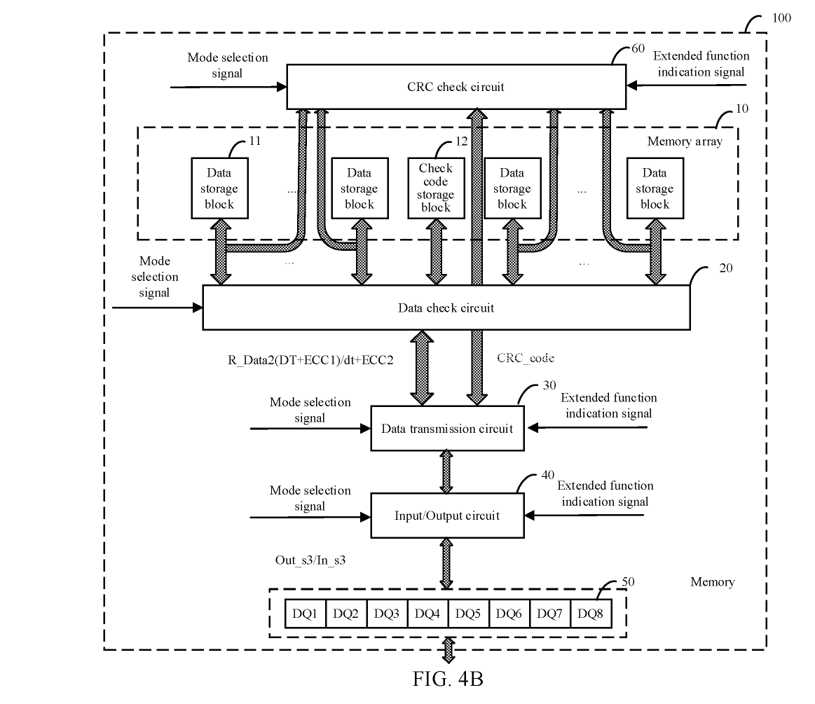

In an embodiment of the present disclosure, referring to FIG. 4A, the memory 100 further includes a data transmission circuit 30, connected between the data check circuit 20 and the input/output circuit 40. The data transmission circuit 30 is configured to: transmit the first read data R_Data1 or the second read data R_Data2 from the data check circuit 20 to the input/output circuit 40, and transmit the first write data W_Data1 or the second write data W_Data2 from the input/output circuit 40 to the data check circuit 20.

It should be noted that the data transmission circuit 30 in the memory 100 provided in this embodiment of the present disclosure is employed only for bidirectional transmission of internal data, such as drive enhancement, delay, synchronization, and level conversion, but does not substantially process the data.

In an embodiment of the present disclosure, referring to FIG. 4B, the data transmission circuit 30 may further receive an extended function indication signal, and when the extended function indication signal indicates that the memory 100 enables the extended function, the data transmission circuit 30 is further configured to: respectively transmit the second read data R_Data2 and the cyclic redundancy check data CRC_code from the data check circuit 20 and the CRC check circuit 60 to the input/output circuit 40 during a read access operation; and transmit the to-be-stored data dt in the third write data W_Data3 and the second check code ECC2 from the input/output circuit 40 to the data check circuit 20, and transmit the cyclic redundancy check data CRC_code in the third write data W_Data3 from the input/output circuit 40 to the CRC check circuit 60 during a write access operation.

It should be noted that in FIG. 4B, the cyclic redundancy check function serving as the extended function is taken as an example for description, and the extended function may alternatively be another function performed in the memory, which is not specifically limited herein.

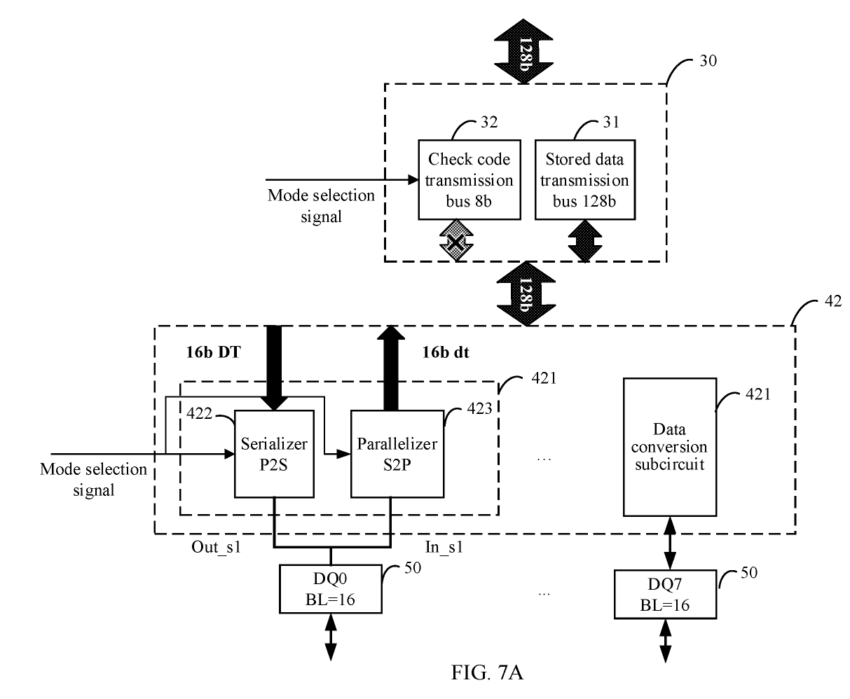

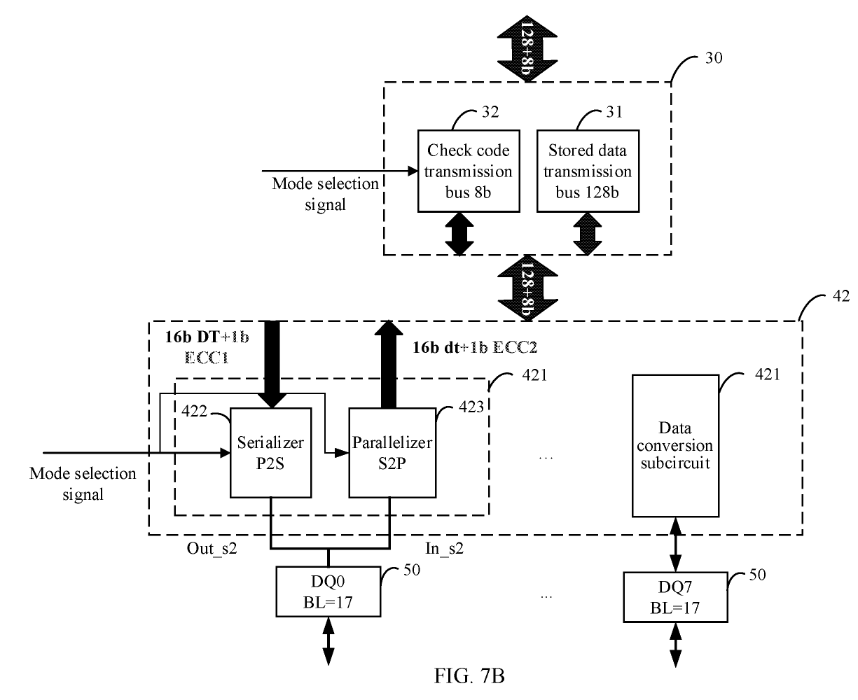

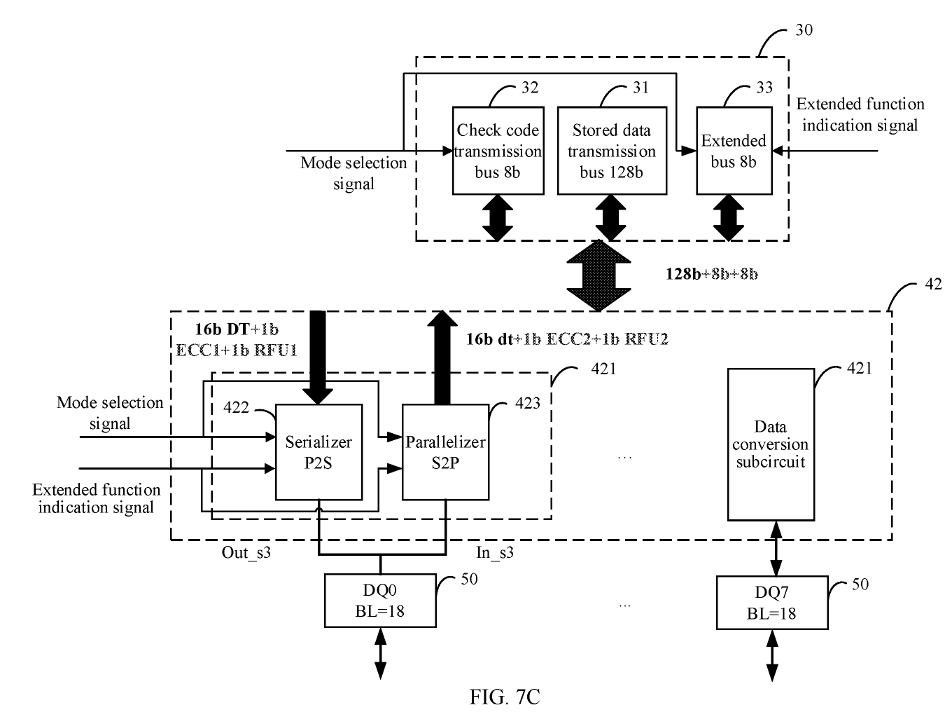

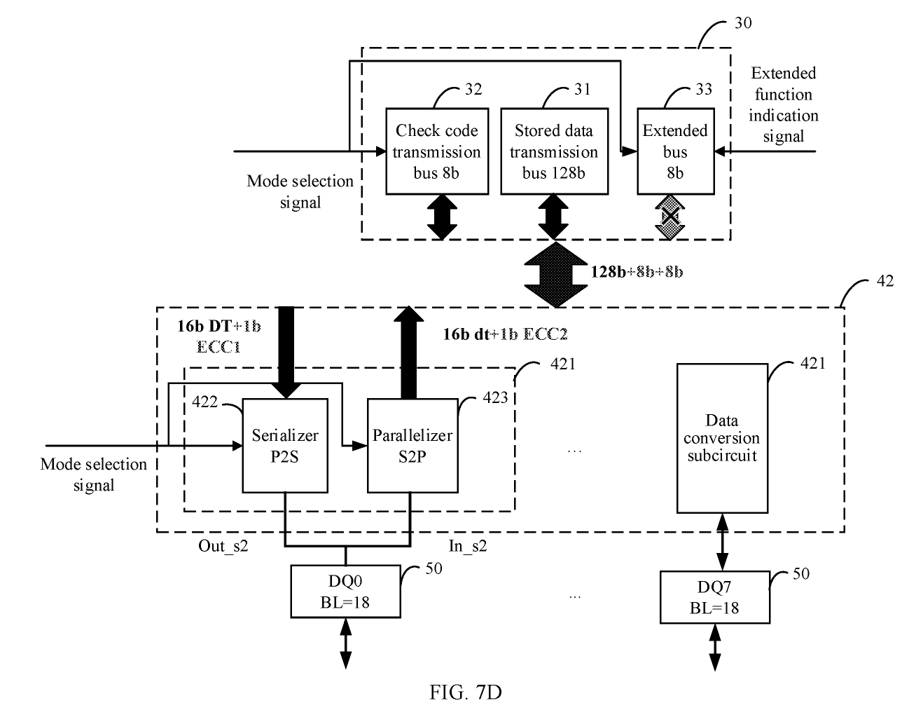

In an embodiment of the present disclosure, referring to FIG. 7A and FIG. 7B, the data transmission circuit 30 includes a stored data transmission bus 31 and a check code transmission bus 32. The stored data transmission bus 31 is configured to transmit the stored data DT or the to-be-stored data dt. The check code transmission bus 32 is configured to: receive the mode selection signal, and transmit the first check code ECC1 or the second check code ECC2 when the mode selection signal indicates that the memory 100 is in the off-die check mode; or be disabled when the mode selection signal indicates that the memory 100 is in the on-die check mode. Specifically, the stored data transmission bus 31 is configured to: transmit the stored data DT in the first read data R_Data1 or the second read data R_Data2 from the data check circuit 20 to the input/output circuit 40, and transmit the to-be-stored data dt in the first write data W_Data1 or the second write data W_Data2 from the input/output circuit 40 to the data check circuit 20. The check code transmission bus 32 is configured to: transmit the first check code ECC1 in the second read data R_Data2 from the data check circuit 20 to the input/output circuit 40, and transmit the second check code ECC2 in the second write data W_Data2 from the input/output circuit 40 to the data check circuit 20.

Herein, when the memory 100 is in the on-die check mode, as shown in FIG. 7B, the memory 100 does not need to receive an external check code through the data port 50 or to externally output a check code through the data port 50. The check code transmission bus 32 in the memory 100 does not need to transmit check data such as the first check code ECC1 or the second check code ECC2, either. In this case, the check code transmission bus 32 may be turned off or disabled, thereby achieving a purpose of reducing power consumption for data transmission in the memory.

It should be noted that, when the memory 100 supports the extended function (the cyclic redundancy check function serving as the extended function is taken as an example for description herein), that is, when the extended function indication signal received by the data transmission circuit 30 indicates that the memory 100 enables the extended function, as shown in FIG. 7C, the stored data transmission bus 31 and the check code transmission bus 32 are also respectively configured to transmit the to-be-stored data dt and the second check code ECC2 in the third write data W_Data3.

In an embodiment of the present disclosure, referring to FIG. 7C and FIG. 7D, the data transmission circuit 30 further includes an extended data bus 33. The extended data bus 33 is configured to: receive the mode selection signal and the extended function indication signal, and transmit the first extended data or the second extended data when the mode selection signal indicates that the memory is in the off-die check mode and the extended function indication signal indicates that the memory is in a state in which the extended function is enabled; otherwise, the extended data bus is disabled.

For the memory 100 that supports the extended function, when the memory 100 is in the on-die check mode or the extended function of the memory is not enabled, as shown in FIG. 7D, the external extended data does not need to be received through the data port 50, or the extended data does not need to be externally output through the data port 50. The extended data bus 33 does not need to transmit the extended data, and the input/output circuit 40 does not need to process the extended data, e.g., cyclic redundancy check data CRC_code. In this case, the extended data bus 33 may be turned off or disabled, thereby achieving a purpose of reducing power consumption for data transmission in the memory 100.

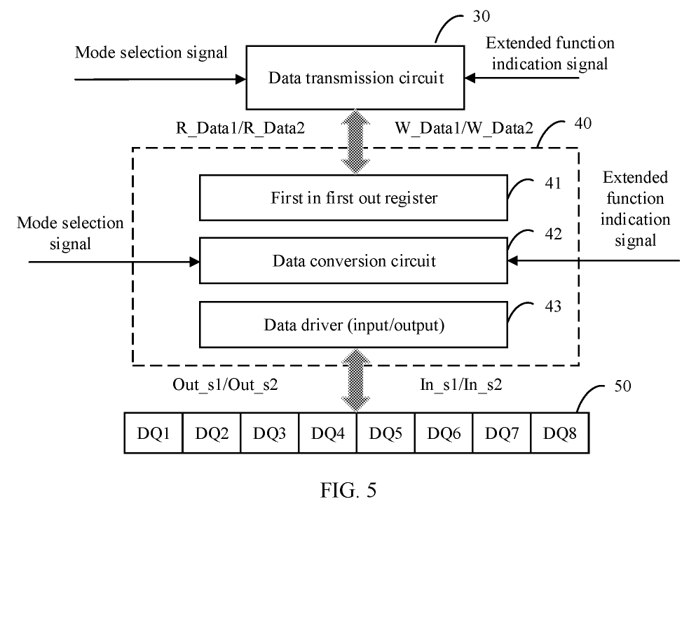

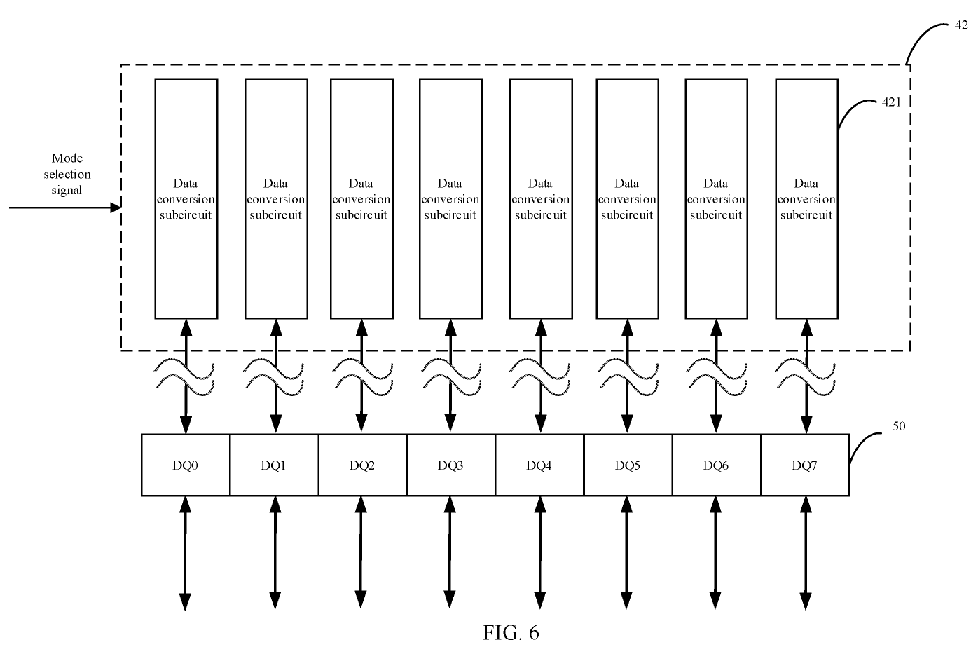

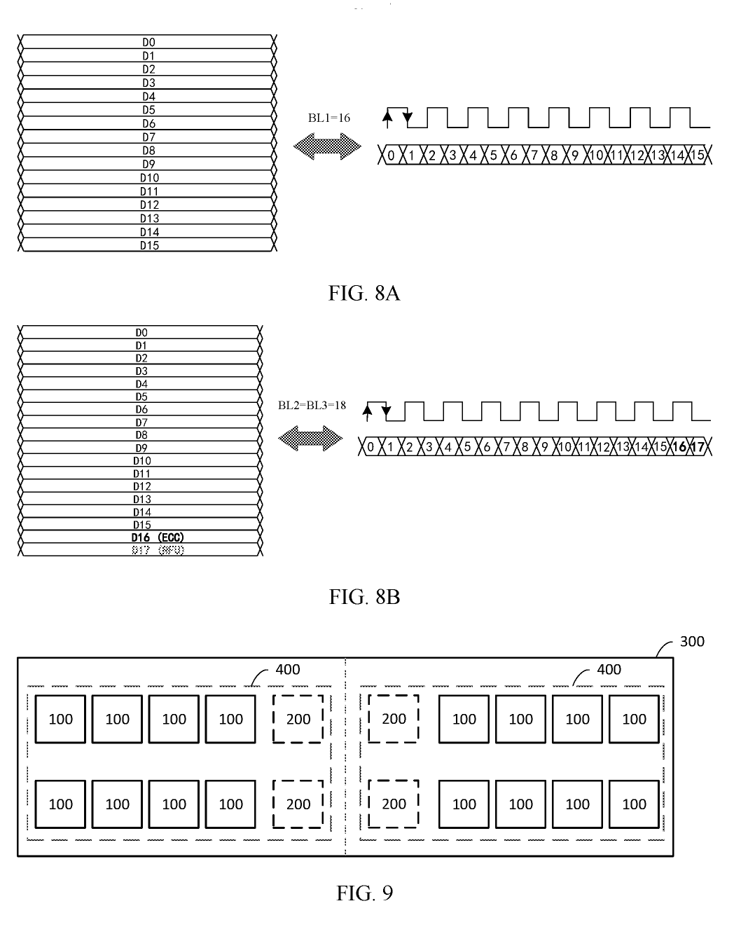

In an embodiment of the present disclosure, referring to FIG. 5, FIG. 6, FIG. 7A to FIG. 7D, FIG. 8A, and FIG. 8B, the input/output circuit 40 includes a data conversion circuit 42, the data conversion circuit 42 includes multiple data conversion subcircuits 421 in a one-to-one correspondence with the multiple data ports 50, and each of the data conversion subcircuits 421 includes a serializer 422 and a parallelizer 423.

The serializer 422 is separately coupled to the data transmission circuit 30 and the corresponding data port 50, and is configured to: serialize, based on the first burst length BL1, a part of the stored data DT received from the data transmission circuit 30 and then generate the first output data string Out_s1 to be output to the corresponding data port 50, when the mode selection signal indicates that the memory 100 is in the on-die check mode, as shown in FIG. 7A and FIG. 8A; or serialize, based on the second burst length BL2, a part of the stored data DT received from the data transmission circuit 30 and a part of the first check code ECC1 and then generate the second output data string Out_s2 to be output to the corresponding data port 50, when the mode selection signal indicates that the memory is in the off-die check mode, as shown in FIG. 7B and FIG. 8B.

The parallelizer 423 is separately coupled to the data transmission circuit 30 and the corresponding data port 50, and is configured to: parallelize the first input data string In_s1 received from the corresponding data port 50 and then generate a part of the first write data W_Data1 to be output to the data transmission circuit 30, when the mode selection signal indicates that the memory 100 is in the on-die check mode, as shown in FIG. 7A and FIG. 8A; or parallelize the second input data string In_s2 received from the corresponding data port 50 and then generate a part of the second write data W_Data2 to be output to the data transmission circuit 30, when the mode selection signal indicates that the memory 100 is in the off-die check mode, as shown in FIG. 7B and FIG. 8B.

As shown in FIG. 7B and FIG. 8B, the first write data W_Data1 correspondingly output by each of the data ports 50 includes a part (16b) of the to-be-stored data dt, and the second write data W_Data2 includes a part (16b) of the to-be-stored data dt and a corresponding part (1b) of the second check code ECC2.

In some embodiments, when the memory 100 supports the extended function, the serializer 422 may alternatively be configured to receive an extended function indication signal, and serialize, based on a third burst length BL3, a part of the stored data DT, a part of the first check code ECC1, and a part of the first extended data RFU1 that are received from the data transmission circuit 30, and then generate a third output data string Out_s3 to be output to the corresponding data port 50, when the mode selection signal indicates that the memory 100 is in the off-die check mode and the extended function indication signal indicates that the memory 100 enables the extended function, as shown in FIG. 7C and FIG. 8B. The parallelizer 423 may alternatively be configured to receive an extended function indication signal, and parallelize the third input data string In_s3 received from the corresponding data port 50, and then generate a part of the to-be-stored data dt, a part of the second check code ECC2, and a part of the second extended data RFU2 to be output to the data transmission circuit 30, when the mode selection signal indicates that the memory 100 is in the off-die check mode and the extended function indication signal indicates that the memory 100 enables the extended function, as shown in FIG. 7C and FIG. 8B.

Herein, the third burst length BL3 and the second burst length BL2 being set to be the same are taken as an example for description. As shown in FIG. 8B, BL2=BL3=18. In some other embodiments, the third burst length BL3 and the second burst length BL2 may alternatively be set to be different. For example, for the DDR4 product, the BL2 may be set to 17, and the BL3 may be set to 18, which is not specifically limited in the present disclosure.

It should be noted that, for the memory 100 that supports the extended function, when the memory 100 is in the on-die check mode or the extended function of the memory is not enabled, as shown in FIG. 7D, the serializer 422 does not need to receive and process the first extended data RFU1, and the parallelizer 423 does not need to process and output the second extended data RFU2, either. For the extended data, the external extended data is received through the data port 50, or the extended data is externally output through the data port 50. In this case, the extended data bus 33 may be turned off or disabled, and the serializer 422 and the parallelizer 423 may be adjusted to skip processing the extended data, thereby shortening a data processing time of the serializer 422 and the parallelizer 423, and reducing internal power consumption of the memory.

In some embodiments, still referring to FIG. 5, the input/output circuit 40 further includes a first in first out register 41 and a data driver 43. The first in first out register 41 is coupled between the data transmission circuit 30 and the data conversion circuit 42, and is configured to: receive and cache the first read data R_Data1 or the second read data R_Data2 from the data transmission circuit 30 during a read operation performed by the memory 100; and receive and cache the parallelized first write data W_Data1 or the parallelized second write data W_Data2 from the data conversion circuit 42 during a write operation performed by the memory 100. The data driver 43 is coupled between the data conversion circuit 42 and the multiple data ports 50, and is configured to: receive the multiple serialized first output data strings Out_s1 or the multiple serialized second output data strings Out_s2 from the data conversion circuit 42 and drive output to the multiple data ports 50, during a read operation performed by the memory 100; and receive the multiple corresponding first input data strings In_s1 or the multiple corresponding second input data strings In_s2 through the multiple data ports 50 and drive output to the data conversion circuit 42, during a write operation performed by the memory 100.

It should be noted that when the memory 100 enables the extended function (the cyclic redundancy check function serving as the extended function is taken as an example for description herein), the first in first out register 41 is alternatively configured to receive and cache the first extended data or the second extended data (not shown in the figure), e.g., cyclic redundancy check data CRC_code. The data driver 43 is alternatively configured to receive multiple serialized third output data strings Out_s3, drive output to the multiple data ports 50, and receive the multiple corresponding third input data strings In_s3 through the multiple data ports 50, and drive output to the data conversion circuit 42.

It should be noted that the memories provided in the foregoing embodiments may be implemented through cooperation with each other. The related technical details described in the previous embodiment are still effective in this embodiment. To reduce repetition, the details are not described herein again.

An embodiment of the present disclosure further provides a storage device. Referring to FIG. 9, the storage device 300 includes at least one storage channel 400, and each storage channel 400 includes multiple memories 100 provided in the foregoing embodiments.

As shown in FIG. 9, the storage device 300 may be a dual inline memory module (Dual Inline Memory Modules, DIMM). Generally, for DIMMs of the left and right storage channels (channel), eight memory chips 100 and two ECC chips 200 are included on each of the left and right sides. The ECC chip herein is a sideband (side-band) ECC chip. Although the sideband ECC chip may support the memory controller in checking and correcting a data error occurring on a complete data transmission link of the storage system, additional hardware costs and system complexity are incurred for the storage device 300. However, based on the memory 100 provided in this embodiment of the present disclosure, a check mode may be flexibly configured by employing a data check circuit. When an error risk of a data transmission link in a storage system is higher, selection of the off-die check mode may be configured, so as to directly send a check code stored on a die and stored data to an external memory controller, so that the memory controller can employ the check code stored on the die to check and correct a data error occurring on a complete data transmission link in the storage system. In this case, the check code storage block in the memory 100 may replace a function of the sideband ECC chip. In other words, the memory 100 provided in the present disclosure may employ the same check code storage block to implement compatibility with a data check function performed on the memory chip and an off-die data check function performed by the memory controller, thereby improving utilization of an on-die check code storage block resource, and saving additional storage resource consumption incurred when the storage device 300 employs another ECC solution such as the sideband ECC. As shown in FIG. 9, based on the memory 100 provided in the present disclosure, four ECC chips 200 in the storage device 300 may be omitted, thereby greatly reducing hardware costs and system complexity of the storage device 300.

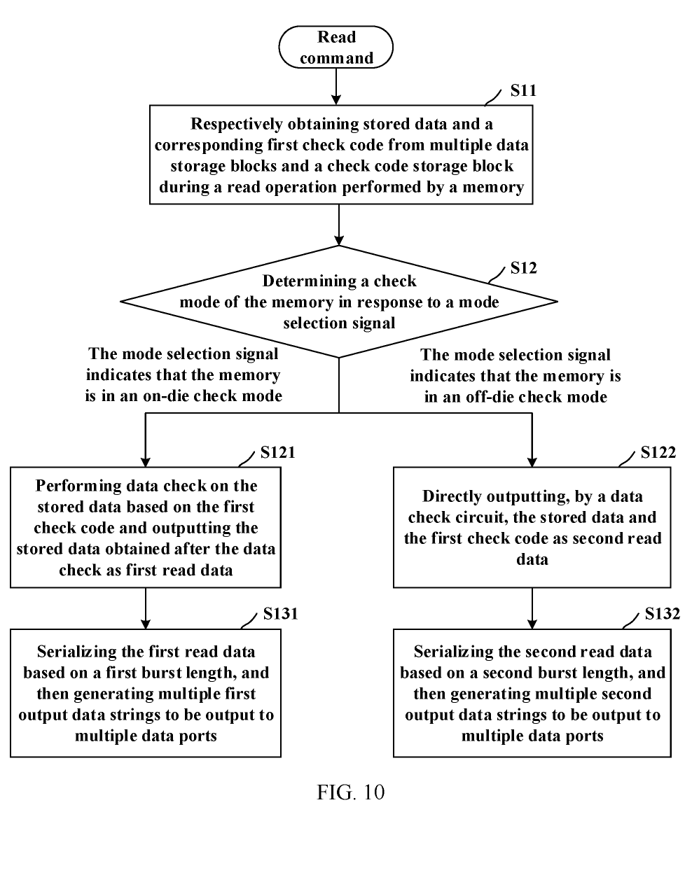

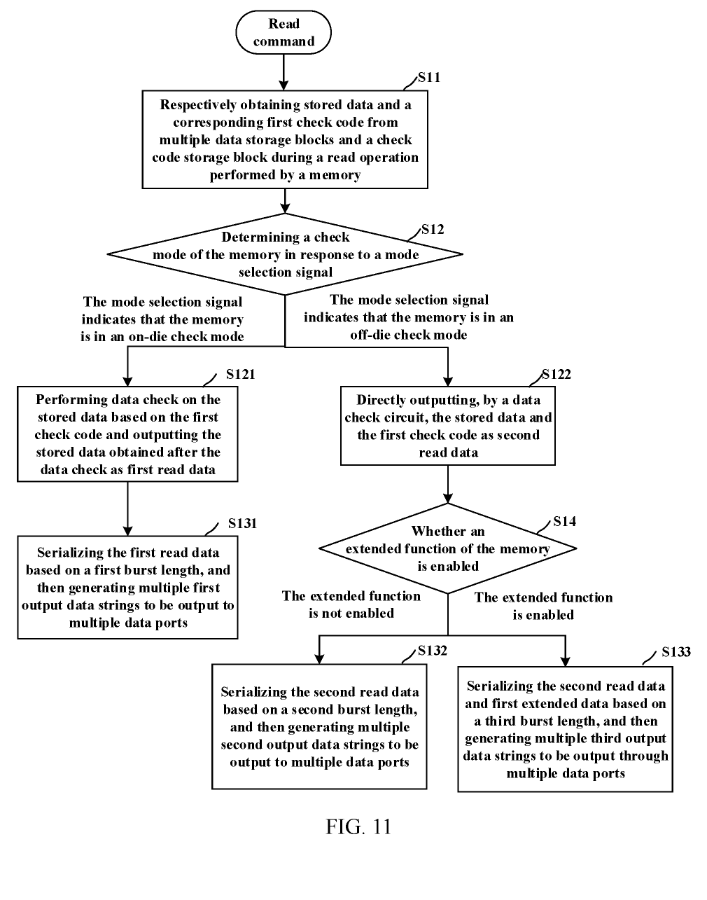

An embodiment of the present disclosure further provides a memory operation method. A memory includes multiple data storage blocks and a check code storage block. Referring to FIG. 10, the operation method includes the following steps:

In the step of S11, stored data and a corresponding first check code are respectively obtained from the multiple data storage blocks and the check code storage block during a read operation performed by the memory.

In the step of S12, a check mode of the memory is determined in response to a mode selection signal.

Specifically, when the mode selection signal indicates that the memory is in an on-die check mode, step S121 is performed: Data check is performed on the stored data based on the first check code and the stored data obtained after the data check is output as first read data; or

when the mode selection signal indicates that the memory is in an off-die check mode, step S122 is performed: The stored data and the first check code are directly output as second read data; the first check code in the second read data being employed by an external memory controller to perform a data check operation on the stored data.

In some embodiments, with reference to FIG. 1A, FIG. 1B, and FIG. 10, a specific process of step S11 includes the following steps: During a read operation performed by the memory 100, the data check circuit 20 respectively obtains the stored data DT and the corresponding first check code ECC1 from the multiple data storage blocks 11 and the check code storage block 12. A specific process of step S12 includes the following steps: The data check circuit 20 determines a check mode of the memory in response to the received mode selection signal; when the mode selection signal indicates that the memory 100 is in the on-die check mode, the data check circuit 20 performs data check on the stored data DT based on the first check code ECC1, and outputs the stored data DT obtained after the data check as the first read data R_Data1; or when the mode selection signal indicates that the memory 100 is in the off-die check mode, the data check circuit 20 directly outputs the stored data DT and the first check code ECC1 as the second read data R_Data2. The first check code ECC1 in the second read data R_Data2 is configured to be output to the external memory controller, and the memory controller performs an off-die data check operation on the stored data DT.

Based on the operation method, during a read operation, the memory may flexibly select, based on the check mode, how to employ and transmit the first check code ECC1 and the stored data DT. When the mode selection signal indicates that the memory is configured to be in the on-die check mode, the first check code ECC1 is configured to provide data protection for an internal data storage process of the memory. The memory directly performs error checking and error correction on the stored data DT based on the first check code ECC1. In this case, the first check code ECC1 has been employed inside the memory and a data check function is completed, and output is not required. Only the stored data DT obtained after the data check needs to be output as the first read data R_Data1. When the mode selection signal indicates that the memory 100 is configured to be in the off-die check mode, the first check code ECC1 is configured to provide data protection for a complete data transmission link of the storage system. The memory no longer performs an on-die data check operation, but directly outputs the stored data DT and the first check code ECC1 as the second read data R_Data2. In this case, the output first check code ECC1 is received by an external memory controller to complete a data check operation on the stored data DT. Therefore, according to the memory operation method provided in this embodiment of the present disclosure, during a read operation, the same check code data is employed to implement compatibility with an on-die data check function and an off-die data check function, thereby improving utilization of an on-die check code storage resource, increasing diversity of a data protection solution, and further saving additional storage resource consumption incurred by employing an off-die data check ECC solution.

In an embodiment of the present disclosure, still referring to FIG. 10, after step S121 or step S122 is completed, the operation method further includes step S13 (not shown in the figure): The first read data or the second read data is output from the memory through multiple data ports after being serialized. Specifically, when the memory is in the on-die check mode, after step S121 is completed, step S131 is performed: The first read data is serialized based on a first burst length, and then multiple first output data strings to be output through the multiple data ports are generated. When the memory is in the off-die check mode, after step S122 is completed, step S132 is performed: The second read data is serialized based on a second burst length, and then multiple second output data strings to be output through the multiple data ports are generated. The first burst length is less than the second burst length.

In some embodiments, with reference to FIG. 2A, FIG. 2B, and FIG. 10, a specific process of step S13 includes the following steps: The input/output circuit 40 disposed in the memory 100 receives the first read data R_Data1 or the second read data R_Data2 from the data check circuit 20, and outputs the first read data R_Data1 or the second read data R_Data2 obtained after serialization from the memory 100 through multiple data ports 50. Specifically, the input/output circuit 40 receives the mode selection signal, and when the mode selection signal indicates that the memory 100 is in the on-die check mode, the input/output circuit 40 serializes the received first read data R_Data1 based on a first burst length BL1 and then generates multiple first output data strings Out_s1 to be output to multiple data ports 50; or when the mode selection signal indicates that the memory 100 is in the off-die check mode, the input/output circuit 40 serializes the received second read data R_Data2 based on a second burst length BL2 and then generates multiple second output data strings Out_s2 to be output to the multiple data ports 50. The first burst length BL1 is less than the second burst length BL2.

In an embodiment of the present disclosure, referring to FIG. 3A, each of the first output data strings Out_s1 includes a part of the stored data DT that is serially output, and each of the second output data strings Out_s2 includes a part of the stored data DT that is serially output and a part of the first check code ECC1.

In an embodiment of the present disclosure, as shown in FIG. 11, when the memory is in the off-die check mode, after step S122 is completed, step S14 is performed: It is determined whether an extended function of the memory is enabled. When the memory is in the off-die check mode and the extended function is not enabled, after step S122 is completed, step S132 is performed: The second read data is serialized based on the second burst length, and then multiple second output data strings to be output through multiple data ports are generated. When the memory is in the off-die check mode and the extended function is enabled, after step S122 is completed, step S133 is performed: The second read data and first extended data are serialized based on a third burst length, and then multiple third output data strings to be output through multiple data ports are generated. Each of the third output data strings includes a part of the stored data that is serially output, a part of the first check code, and a part of the first extended data. However, when the memory is in the on-die check mode, after step S121 is completed, step S131 is directly performed: The first read data is serialized based on the first burst length, and then multiple first output data strings to be output through multiple data ports are generated.

In some embodiments, with reference to FIG. 2A to FIG. 2D, FIG. 3A, and FIG. 11, after step S122 is completed, step S14 is performed, which specifically includes the following steps: The input/output circuit 40 further receives an extended function indication signal, and determines, based on the extended function indication signal, whether an extended function of the memory is enabled. When the mode selection signal indicates that the memory 100 is in the off-die check mode and the extended function indication signal indicates that the memory enables the extended function, the input/output circuit 40 serializes the received second read data R_Data2 and first extended data RFU1 based on a third burst length BL3, and then generates multiple third output data strings Out_s3 to be output to the multiple data ports 50. As shown in FIG. 3A, each of the third output data strings Out_s3 includes a part of the stored data DT that is serially output, a part of the first check code ECC1, and a part of the first extended data RFU1. In this case, when the memory is in the off-die check mode and the extended function is not enabled, the input/output circuit 40 serializes the received second read data R_Data2 based on the second burst length BL2, and then generates multiple second output data strings Out_s2 to be output to the multiple data ports 50.

Herein, the third burst length BL3 and the second burst length BL2 may be set to be the same. As shown in FIG. 3A to FIG. 3D, BL2=BL3=18. The third burst length BL3 and the second burst length BL2 may alternatively be set to be different. For example, for the DDR4 product, the BL2 may be set to 17 and the BL3 may be set to 18.

It should be noted that the extended function may be a cyclic redundancy check function, and the corresponding first extended data RFU1 may be cyclic redundancy check data CRC_code. Alternatively, the extended function may be another function performed in the memory.

It should be further noted that the memory operation methods provided in the foregoing embodiments are all completed during a read access operation that starts to be performed after the memory receives a read command. In addition, the foregoing memory operation methods may be all applied to the memory 100 in the foregoing embodiments. For details not disclosed in the embodiments of the operation methods, refer to descriptions of the foregoing embodiments of the memory 100 for understanding. Details are not described herein again.

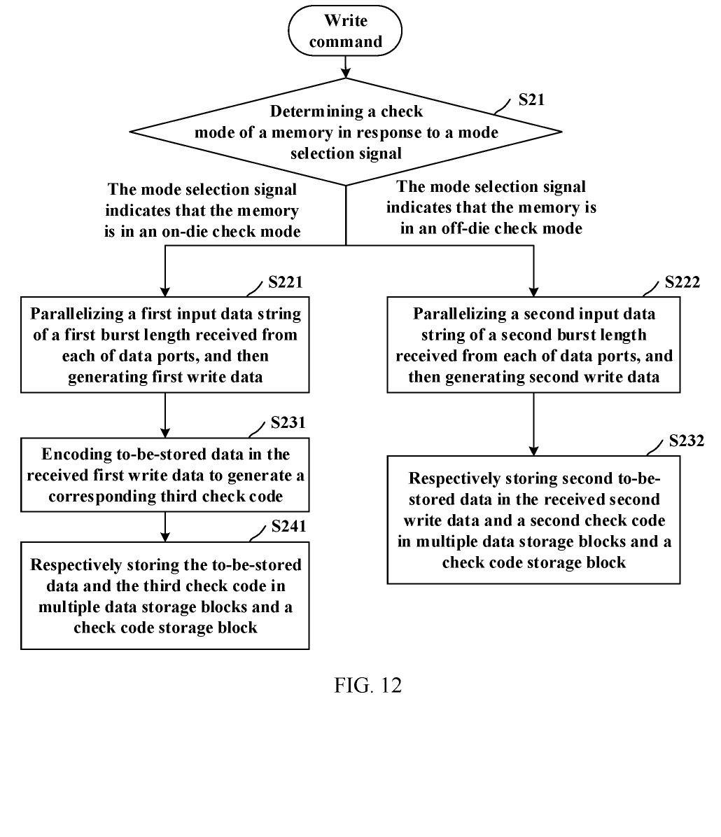

An embodiment of the present disclosure further provides another memory operation method. A memory includes multiple data storage blocks and a check code storage block. Referring to FIG. 12, the operation method includes the following steps:

In the step of S21, a check mode of the memory is determined in response to a mode selection signal during a write operation performed by the memory.

When the mode selection signal indicates that the memory is in an on-die check mode, step S221 is performed: A first input data string of a first burst length received from each of data ports is parallelized, and then first write data is generated.

When the mode selection signal indicates that the memory is in an off-die check mode, step S222 is performed: A second input data string of a second burst length received from each of data ports is parallelized, and then second write data is generated.

The second burst length is greater than the first burst length, the first write data includes to-be-stored data, the second write data includes the to-be-stored data and a corresponding second check code, the first input data string includes a part of the to-be-stored data that is serially input, and the second input data string includes a part of the to-be-stored data that is serially input and a part of the second check code.

In some embodiments, with reference to FIG. 2E, FIG. 2F, and FIG. 12, a specific process of step S21 includes the following steps: During a write operation performed by the memory 100, the input/output circuit 40 determines a check mode of the memory based on the received mode selection signal. When the mode selection signal indicates that the memory 100 is in the on-die check mode, as shown in FIG. 2E, the input/output circuit 40 parallelizes a first input data string In_s1 of a first burst length BL1 received from each of the data ports 50, and then generates first write data W_Data1 to be output to the data check circuit 20; or when the mode selection signal indicates that the memory 100 is in the off-die check mode, as shown in FIG. 2F, the input/output circuit 40 parallelizes a second input data string In_s2 of a second burst length BL2 received from each of the data ports 50, and then generates second write data W_Data2 to be output to the data check circuit 20. The first write data W_Data1 includes to-be-stored data dt, the second write data W_Data2 includes the to-be-stored data dt and a corresponding second check code ECC2, the first input data string In_s1 includes a part of the to-be-stored data dt that is serially input, and the second input data string In_s2 includes a part of the to-be-stored data dt that is serially input and a part of the second check code ECC2.

Based on the foregoing operation method, during the read operation, the memory may flexibly choose to receive and process specific write data based on the check mode. When the mode selection signal indicates that the memory is configured to be in an on-die check mode, the memory receives a first input data string including only to-be-stored data and processes the first input data string to generate the first write data. In this case, the memory needs to generate an internal third check code ECC3 based on the to-be-stored data, and then implements on-die checking of the data. The memory may store the to-be-stored data dt and the internally generated third check code ECC3 into a data storage block and a check code storage block. When the mode selection signal indicates that the memory 100 is configured to be in an off-die check mode, the memory receives a second input data string including the to-be-stored data and a second check code and processes the second input data string to generate the second write data. The second check code ECC2 corresponding to the to-be-stored data dt is directly generated and sent by an external memory controller. In this case, the memory does not need to generate the internal third check code based on the to-be-stored data, and the memory may directly store the to-be-stored data dt in the second write data W_Data2 and the externally received second check code ECC2 into a data storage block and a check code storage block. Therefore, according to the foregoing memory operation method provided in this embodiment of the present disclosure, during a write operation, compatibility with an on-die data check function and an off-die data check function is implemented based on the mode selection signal, thereby improving utilization of an on-die check code storage resource, increasing diversity of a data protection solution, and further saving additional storage resource consumption incurred by employing an off-die data check ECC solution.

In an embodiment of the present disclosure, still referring to FIG. 12, the operation method further includes the following steps: When the memory is in the on-die check mode, after step S221 is completed, step S231 and step S241 are performed: The to-be-stored data in the received first write data is encoded to generate a corresponding third check code, and the to-be-stored data and the third check code are respectively stored in the multiple data storage blocks and the check code storage block; or when the memory is in the off-die check mode, after step S222 is completed, step S232 is performed: The to-be-stored data in the received second write data and the second check code are respectively stored in the multiple data storage blocks and the check code storage block.

In some embodiments, with reference to FIG. 2E, FIG. 2F, and FIG. 12, when the memory 100 is in the on-die check mode, the data check circuit 20 encodes the to-be-stored data dt in the received first write data W_Data1 to generate a corresponding third check code ECC3, and respectively stores the to-be-stored data dt and the third check code ECC3 in the multiple data storage blocks 11 and the check code storage block 12; or when the memory 100 is in the off-die check mode, the data check circuit 20 respectively stores the to-be-stored data dt in the received second write data W_Data2 and the second check code ECC2 in the multiple data storage blocks 11 and the check code storage block 12.

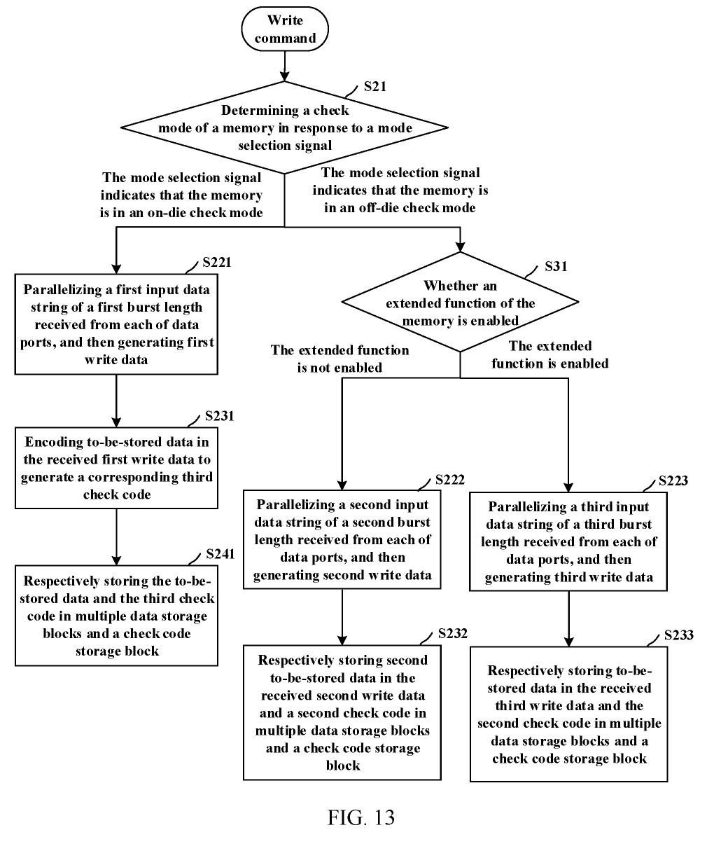

In an embodiment of the present disclosure, referring to FIG. 13, when the mode selection signal indicates that the memory is in the off-die check mode, the operation method further includes step S31: It is determined whether an extended function of the memory is enabled. When the memory is in the off-die check mode and the extended function is not enabled, step S222 and step S232 are successively performed: The second input data string received from each of the data ports is parallelized, and then the second write data is generated; and the second read data is serialized based on the second burst length, and then multiple second output data strings to be output through multiple data ports are generated; or when the memory is in the off-die check mode and the extended function is enabled, step S223 and step S233 are performed: The third input data string of the third burst length received from each of the data ports is parallelized, and then the third write data is generated; and the to-be-stored data in the received third write data and the second check code are respectively stored in the multiple data storage blocks and the check code storage block. The third write data includes the to-be-stored data, the corresponding second check code, and second extended data, and the third input data string includes a part of the to-be-stored data that is serially input, a part of the second check code, and a part of the second extended data.

In some embodiments, with reference to FIG. 2E to FIG. 2H, FIG. 3A, and FIG. 13, after step S21 is performed, when it is determined that the memory is in the off-die check mode, step S31 is performed, which specifically includes the following steps: The input/output circuit 40 further receives an extended function indication signal, and determines, based on the extended function indication signal, whether an extended function of the memory is enabled. When the mode selection signal indicates that the memory 100 is in the off-die check mode and the extended function indication signal indicates that the memory enables the extended function, a third input data string In_s3 of a third burst length BL3 received from each of the data ports 50 is parallelized and then third write data W_Data3 to be output to the data check circuit 20 is generated. The third write data W_Data3 includes the to-be-stored data dt, the corresponding second check code ECC2, and second extended data RFU2. The third input data string In_s3 includes a part of the to-be-stored data dt that is serially input, a part of the second check code ECC2, and a part of the second extended data RFU2. On the contrary, when the memory is in the off-die check mode and the extended function is not enabled, step S222 is performed: The input/output circuit 40 parallelizes the second input data string In_s2 of the second burst length BL2 received from each of the data ports 50, and then generates the second write data W_Data2 to be output to the data check circuit 20.

Herein, the third burst length BL3 and the second burst length BL2 may be set to be the same. As shown in FIG. 3A to FIG. 3D, BL2=BL3=18. The third burst length BL3 and the second burst length BL2 may alternatively be set to be different. For example, for the DDR4 product, the BL2 may be set to 17 and the BL3 may be set to 18.

It should be noted that the extended function may be a cyclic redundancy check function, and the corresponding first extended data RFU1 may be cyclic redundancy check data CRC_code. Alternatively, the extended function may be another function performed in the memory.

It should be further noted that the memory operation methods provided in the foregoing embodiments are all completed during a write access operation that starts to be performed after the memory receives a write command. In addition, the foregoing memory operation methods may be all applied to the memory 100 in the foregoing embodiments. For details not disclosed in the embodiments of the operation methods, refer to descriptions of the foregoing embodiments of the memory 100 for understanding. Details are not described herein again.

It should be noted that in this specification, the terms "include", "comprise", or any other variant thereof are intended to cover non-exclusive inclusion, so that a process, method, article, or apparatus including a series of elements includes not only those elements but also other elements that are not expressly listed, or further includes elements inherent to such a process, method, article, or apparatus. An element preceded by "includes a ..." does not, without more constraints, preclude the presence of additional identical elements in the process, method, article, or apparatus including the element.

The sequence numbers of the foregoing embodiments of the present disclosure are merely for the purpose of description, and are not intended to indicate priorities of the embodiments. The methods disclosed in the several method embodiments provided in the present disclosure may be randomly combined when there is no conflict, to obtain new method embodiments. The features disclosed in the several product embodiments provided in the present disclosure may be randomly combined when there is no conflict, to obtain new product embodiments. The features disclosed in the several method or device embodiments provided in the present disclosure may be randomly combined when there is no conflict, to obtain new method embodiments or new device embodiments.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A memory, comprising:
a plurality of data storage blocks and a check code storage block; and
a data check circuit, configured to: respectively obtain stored data and a corresponding first check code from the plurality of data storage blocks and the check code storage block, and determine, in response to a received mode selection signal, whether to perform a data check operation;
the data check circuit being further configured to: perform data check on the stored data based on the first check code, and output the stored data obtained after the data check as first read data, when the mode selection signal indicates that the memory is in an on-die check mode; or directly output the stored data and the first check code as second read data when the mode selection signal indicates that the memory is in an off-die check mode; the first check code in the second read data being employed by an external memory controller to perform a data check operation on the stored data.

2. The memory according to claim 1, wherein the memory further comprises:
an input/output circuit, configured to: receive the mode selection signal, and serialize the received first read data based on a first burst length and then generate a plurality of first output data strings to be output to a plurality of data ports, when the mode selection signal indicates that the memory is in the on-die check mode; or serialize the received second read data based on a second burst length and then generate a plurality of second output data strings to be output to the plurality of data ports, when the mode selection signal indicates that the memory is in the off-die check mode; the first burst length being less than the second burst length.

3. The memory according to claim 2, wherein
each of the first output data strings comprises a part of the stored data that is serially output, and each of the second output data strings comprises a part of the stored data that is serially output and a part of the first check code.

4. The memory according to claim 2, wherein
the input/output circuit is further configured to: receive an extended function indication signal, and serialize the received second read data and first extended data based on a third burst length and then generate a plurality of third output data strings to be output to the plurality of data ports, when the mode selection signal indicates that the memory is in the off-die check mode and the extended function indication signal indicates that the memory enables an extended function;
each of the third output data strings comprising a part of the stored data that is serially output, a part of the first check code, and a part of the first extended data.

5. The memory according to claim 2, wherein
the input/output circuit is further configured to: parallelize a first input data string of a first burst length received from each of the data ports and then generate first write data to be output to the data check circuit, when the mode selection signal indicates that the memory is in the on-die check mode; or parallelize a second input data string of a second burst length received from each of the data ports and then generate second write data to be output to the data check circuit, when the mode selection signal indicates that the memory is in the off-die check mode; the first write data comprising to-be-stored data, the second write data comprising the to-be-stored data and a corresponding second check code, the first input data string comprising a part of the to-be-stored data that is serially input, and the second input data string comprising a part of the to-be-stored data that is serially input and a part of the second check code.

6. The memory according to claim 5, wherein
the data check circuit is further configured to: encode the to-be-stored data in the received first write data to generate a corresponding third check code, and respectively store the to-be-stored data and the third check code in the plurality of data storage blocks and the check code storage block, when the mode selection signal indicates that the memory is in the on-die check mode; or respectively store the to-be-stored data in the received second write data and the second check code in the plurality of data storage blocks and the check code storage block when the mode selection signal indicates that the memory is in the off-die check mode.

7. The memory according to claim 4, wherein
the input/output circuit is further configured to: receive an extended function indication signal, and parallelize a third input data string of a third burst length received from each of the data ports and then generate third write data to be output to the data check circuit, when the mode selection signal indicates that the memory is in the off-die check mode and the extended function indication signal indicates that the memory enables an extended function;
the third write data comprising the to-be-stored data, the corresponding second check code, and second extended data, and the third input data string comprising a part of the to-be-stored data that is serially input, a part of the second check code, and a part of the second extended data.

8. The memory according to claim 2, wherein the memory further comprises:
a data transmission circuit, connected between the data check circuit and the input/output circuit, the data transmission circuit being configured to: transmit the first read data or the second read data from the data check circuit to the input/output circuit, and transmit the first write data or the second write data from the input/output circuit to the data check circuit.

9. The memory according to claim 8, wherein the input/output circuit comprises a data conversion circuit, the data conversion circuit comprises a plurality of data conversion subcircuits in a one-to-one correspondence with the plurality of data ports, and each of the data conversion subcircuits comprises a serializer and a parallelizer;
the serializer is separately coupled to the data transmission circuit and the corresponding data port, and is configured to: serialize, based on the first burst length, a part of the stored data received from the data transmission circuit and then generate the first output data string to be output to the corresponding data port, when the mode selection signal indicates that the memory is in the on-die check mode; or serialize, based on the second burst length, a part of the stored data received from the data transmission circuit and a part of the first check code and then generate the second output data string to be output to the corresponding data port, when the mode selection signal indicates that the memory is in the off-die check mode; and
the parallelizer is separately coupled to the data transmission circuit and the corresponding data port, and is configured to: parallelize the first input data string received from the corresponding data port and then generate a part of the first write data to be output to the data transmission circuit, when the mode selection signal indicates that the memory is in the on-die check mode; or parallelize the second input data string received from the corresponding data port and then generate a part of the second write data to be output to the data transmission circuit, when the mode selection signal indicates that the memory is in the off-die check mode.

10. The memory according to claim 9, wherein the input/output circuit further comprises a first in first out register and a data driver;
the first in first out register is coupled between the data transmission circuit and the data conversion circuit, and is configured to: receive and cache the first read data or the second read data from the data transmission circuit during a read operation performed by the memory; and receive and cache the parallelized first write data or the parallelized second write data from the data conversion circuit during a write operation performed by the memory; and
the data driver is coupled between the data conversion circuit and the plurality of data ports, and is configured to: receive the plurality of serialized first output data strings or the plurality of serialized second output data strings from the data conversion circuit and drive output to the plurality of data ports, during a read operation performed by the memory; and receive the plurality of corresponding first input data strings or the plurality of corresponding second input data strings through the plurality of data ports and drive output to the data conversion circuit, during a write operation performed by the memory.

11. The memory according to claim 8, wherein the data transmission circuit comprises a stored data transmission bus and a check code transmission bus;
the stored data transmission bus is configured to transmit the stored data or the to-be-stored data; and
the check code transmission bus is configured to: receive the mode selection signal, and transmit the first check code or the second check code when the mode selection signal indicates that the memory is in the off-die check mode; or be disabled when the mode selection signal indicates that the memory is in the on-die check mode.

12. The memory according to claim 8, wherein the data transmission circuit further comprises an extended data bus;
the extended data bus being configured to: receive the mode selection signal and the extended function indication signal, and transmit the first extended data or the second extended data when the mode selection signal indicates that the memory is in the off-die check mode and the extended function indication signal indicates that the memory is in a state in which the extended function is enabled; otherwise, the extended data bus being disabled.

13. A storage device, comprising at least one storage channel, each of the storage channel comprising a plurality of memories according to claim 1.

14. An operation method for a memory, the memory comprising a plurality of data storage blocks and a check code storage block, and the operation method comprising:
respectively obtaining stored data and a corresponding first check code from the plurality of data storage blocks and the check code storage block;
determining a check mode of the memory in response to a mode selection signal; and
performing data check on the stored data based on the first check code and outputting the stored data obtained after the data check as first read data, when the mode selection signal indicates that the memory is in an on-die check mode; or
directly outputting the stored data and the first check code as second read data when the mode selection signal indicates that the memory is in an off-die check mode;
the first check code in the second read data being employed by an external memory controller to perform a data check operation on the stored data.

15. The operation method according to claim 14, wherein the operation method further comprises:
outputting the first read data or the second read data from the memory through a plurality of data ports after being serialized;
the first read data being serialized based on a first burst length, and then a plurality of first output data strings to be output through the plurality of data ports being generated, when the memory is in the on-die check mode; or the second read data being serialized based on a second burst length, and then a plurality of second output data strings to be output through the plurality of data ports being generated, when the memory is in the off-die check mode; the first burst length being less than the second burst length.

16. The operation method according to claim 14, wherein after the directly outputting the stored data and the first check code as second read data, the operation method further comprises:
determining whether an extended function of the memory is enabled; and
serializing the second read data and first extended data based on a third burst length, and then generating a plurality of third output data strings to be output through a plurality of data ports, if the memory is in the off-die check mode and the extended function is enabled;
each of the third output data strings comprising a part of the stored data that is serially output, a part of the first check code, and a part of the first extended data.

17. An operation method for a memory, the operation method comprising:
determining a check mode of the memory in response to a mode selection signal; and
parallelizing a first input data string of a first burst length received from each of data ports, and then generating first write data, when the mode selection signal indicates that the memory is in an on-die check mode; or
parallelizing a second input data string of a second burst length received from each of data ports, and then generating second write data, when the mode selection signal indicates that the memory is in an off-die check mode;
the second burst length being greater than the first burst length, the first write data comprising to-be-stored data, the second write data comprising the to-be-stored data and a corresponding second check code, the first input data string comprising a part of the to-be-stored data that is serially input, and the second input data string comprising a part of the to-be-stored data that is serially input and a part of the second check code.

18. The operation method according to claim 17, wherein the memory comprises a plurality of data storage blocks and a check code storage block, and the operation method further comprises:
encoding the to-be-stored data in the received first write data to generate a corresponding third check code, and respectively storing the to-be-stored data and the third check code in the plurality of data storage blocks and the check code storage block, when the memory is in the on-die check mode; or
respectively storing the to-be-stored data in the received second write data and the second check code in the plurality of data storage blocks and the check code storage block, when the memory is in the off-die check mode.

19. The operation method according to claim 17, wherein when the mode selection signal indicates that the memory is in the off-die check mode, the operation method further comprises:
determining whether an extended function of the memory is enabled; and
parallelizing a third input data string of a third burst length received from each of the data ports, and then generating third write data, if the memory is in the off-die check mode and the extended function is enabled;
the third write data comprising the to-be-stored data, the corresponding second check code, and second extended data, and the third input data string comprising a part of the to-be-stored data that is serially input, a part of the second check code, and a part of the second extended data.
